(19) United States
(12) Patent Application Publication
(10) Pub. No.: US 2025/0006811 A1
(43) Pub. Date: Jan. 2, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Ta-Chun LIN, Hsinchu (TW); Chun-Wing Yeung, Hsinchu (TW); Feng-Ming CHANG, Hsinchu County (TW); Jhon Jhy Liaw, Hsinchu County (TW)

(73) Assignee: Taiwan Semiconductor Manufacturing Company, Ltd., Hsinchu (TW)

(21) Appl. No.: 18/344,860

(22) Filed: Jun. 30, 2023

(51) Int. Cl. H01L 29/423; H01L 27/092; H01L 29/06; H01L 29/08; H01L 29/66; H01L 29/775

(52) U.S. Cl. CPC H01L 29/42392; H01L 27/092; H01L 29/0673; H01L 29/0847; H01L 29/66439; H01L 29/66545; H01L 29/66553; H01L 29/775; H01L 2029/42388

(57) ABSTRACT

A semiconductor device and a manufacturing method thereof are provided. The semiconductor device includes a semiconductor substrate, semiconductor nanosheets vertically stacked upon one another and disposed above the semiconductor substrate, a gate structure surrounding each of the semiconductor nanosheets, inner spacers laterally covering the gate structure and interposed between the semiconductor nanosheets, and source/drain (S/D) regions disposed over the semiconductor substrate and laterally abutting the semiconductor nanosheets. The semiconductor nanosheets serve as channel regions. A bottommost inner spacer of the inner spacers underlying a bottommost semiconductor nanosheet of the semiconductor nanosheets is thinner than a topmost inner spacer of the inner spacers underlying a topmost semiconductor nanosheet of the semiconductor nanosheets. The S/D regions are separated from the gate structure through the inner spacers.

### BACKGROUND

The semiconductor integrated circuit (IC) industry has experienced a fast-paced growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs. However, such scaling has also introduced increased complexity to the semiconductor manufacturing process. Thus, the realization of continued advances in ICs and devices calls for similar advances in semiconductor manufacturing processes and technology.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 14 illustrate schematic cross-sectional views of intermediate steps during a process for forming a semiconductor device, in accordance with some embodiments.

FIGS. 15 through 22 illustrate schematic cross-sectional views of intermediate steps during a process for forming a semiconductor device, in accordance with some embodiments.

FIGS. 23 through 29 illustrate schematic cross-sectional views of intermediate steps during a process for forming a semiconductor device, in accordance with some embodiments.

FIGS. 30 through 36 illustrate schematic cross-sectional views of intermediate steps during a process for forming a semiconductor device, in accordance with some embodiments.

FIGS. 37 through 40 illustrate schematic cross-sectional views of variations of a semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The embodiments of the disclosure describe methods for forming a semiconductor device (or a portion of a nanostructure transistor device) with reduced resistance and improved performance. The nanostructure transistor device (also referred to as a gate-all-around (GAA) transistor device) may include a gate structure wrapping around the perimeter of one or more nanosheets (i.e. channel regions) for improved control of channel current flow. The embodiments are not limited in the context. The semiconductor device may be included in microprocessors, memories, and/or other ICs. Moreover, it is understood that the semiconductor device may be part of an IC that further includes a number of other devices such as resistors, capacitors, inductors, fuses, etc. It is understood that the structures illustrated in the drawings are simplified for a better understanding of the concepts of the disclosure.

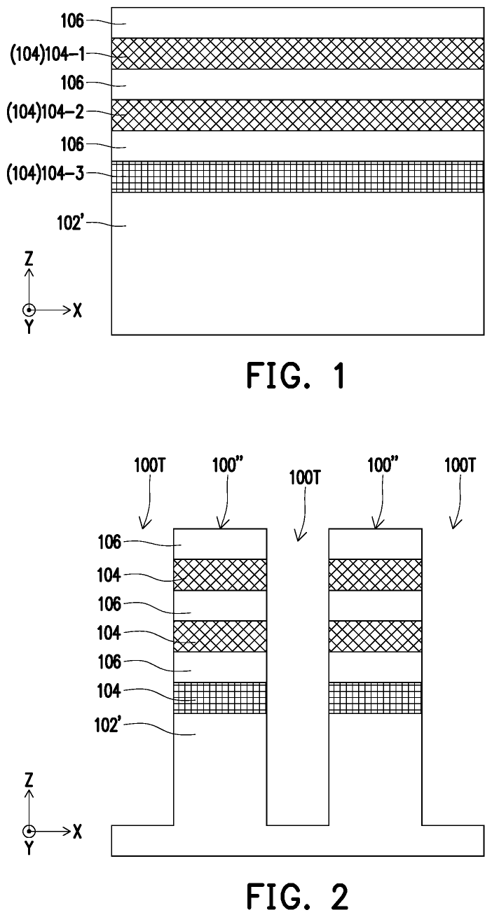

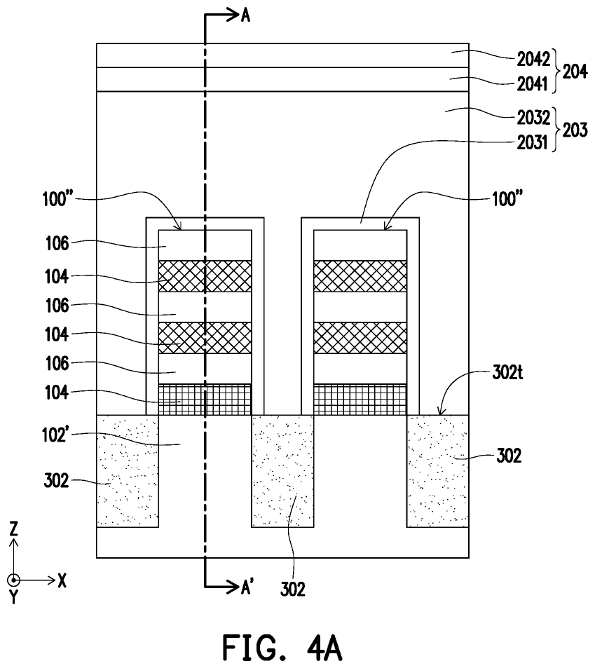

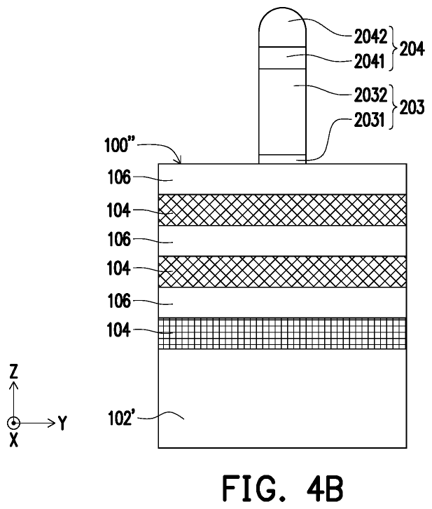

FIGS. 1 through 14 illustrate schematic cross-sectional views of intermediate steps during a process for forming a semiconductor device, according to some embodiments. For clarity of illustrations, in the drawings are illustrated the orthogonal axes (X, Y and Z) of the Cartesian coordinate system according to which the views are oriented. It should be noted that FIGS. 1-4A are cross-sectional views of the structure taken at the X-Z plane, FIG. 4B is a cross-sectional view of the structure illustrated in FIG. 4A taken along the line A-A′, and FIGS. 4B and 5-14 are cross-sectional views taken at the Y-Z plane and illustrating the following steps of forming a semiconductor device. Although FIGS. 1-14 are described as a series of acts, these acts are not limiting in that the order of the acts can be altered in other embodiments, and the methods disclosed are also applicable to other structures. In alternative embodiments, some acts that are illustrated and/or described may be omitted in whole or in part.

Referring to FIG. 1, a stack of first semiconductor layers 104 (e.g., 104-1, 104-2, and 104-3) and second semiconductor layers 106 may be formed on a semiconductor substrate 102′. In some embodiments, the semiconductor substrate 102′ includes a crystalline silicon substrate or a bulk silicon substrate (e.g., wafer). In some embodiments, the semiconductor substrate 102′ is made of a suitable elemental semiconductor (e.g., germanium), a suitable compound semiconductor (e.g., gallium arsenide, silicon carbide, indium arsenide, or indium phosphide), a suitable alloy semiconductor (e.g., silicon germanium carbide, gallium arsenic phosphide, or gallium indium phosphide), and/or the like. In some embodiments, the semiconductor substrate 102′ includes a silicon-on-insulator (SOI) substrate or other suitable substrate. The semiconductor substrate 102′ may include various doped regions (not individually shown) doped with p-type or n-type dopants, where the doped regions may be configured for an n-type region, or alternatively, configured for a p-type region.

The first semiconductor layers 104 and the second semiconductor layers 106 may be alternately stacked upon one another (e.g., along the Z-direction) to form a stack. In some embodiments, the first semiconductor layers 104 and the second semiconductor layers 106 are grown from the semiconductor substrate 102′. For example, each of the first semiconductor layers 104 and the second semiconductor layers 106 is grown by a molecular beam epitaxy (MBE) process, a chemical vapor deposition (CVD) process, or any suitable growth process. The first semiconductor layers 104 may be considered sacrificial layers in the sense that they are removed in the subsequent process (see FIG. 12). The second semiconductor layers 106 may be semiconductor nanosheets that serve as channel regions in the semiconductor device. The terms “semiconductor nanosheets” and “channel regions/layers” may be used interchangeably herein.

In some embodiments, the bottommost one of the first semiconductor layers (i.e. the bottommost first semiconductor layer 104-3) is formed on the semiconductor substrate 102′, with the remaining second and first semiconductor layers (106 and 104) alternately stacked on top. However, either the first semiconductor layer 104 or the second semiconductor layer 106 may be the bottommost layer (or the layer most proximate from the semiconductor substrate 102′). In some embodiments, the second semiconductor layer 106 may be the topmost layer (or the layer most distanced from the semiconductor substrate 102′) of the stack. It should be noted that the number of the first semiconductor layers 104 and the number of the second semiconductor layers 106 illustrated herein are examples and construe no limitation in the disclosure.

The first semiconductor layers 104 and the second semiconductor layers 106 may include different materials (or compositions) that provide for different oxidation rates and/or different etch selectivity between the layers. For example, the second semiconductor layers 106 are formed of the same material as the semiconductor substrate 102′, while the first semiconductor layers 104 may be formed of a different material which is selectively removed with respect to the material of the semiconductor substrate 102′ and the second semiconductor layers 106. In some embodiments, the first semiconductor layers 104 may each include silicon germanium (SiGe). In some embodiments, the second semiconductor layers 106 may each include silicon, where the respective second semiconductor layer 106 may be undoped or substantially dopant-free. In some embodiments, the second semiconductor layers 106 are doped with a p-type dopant such as boron, aluminum, indium, and gallium. In some embodiments, the second semiconductor layers 106 are doped with an n-type dopant such as phosphorus, arsenic, antimony. Either of the first semiconductor layers 104 and the second semiconductor layers 106 may include other materials, for example, a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GaInP, and/or GaInAsP, any other suitable material, or combinations thereof.

With continued reference to FIG. 1, in the example where the first semiconductor layers 104 are formed of SiGe, the topmost first semiconductor layer 104-1 may contain SiGe with a first percentage of Ge, and the bottommost first semiconductor layer 104-3 may contain SiGe with a second percentage of Ge, where the first percentage is different from the second percentage. In some embodiments, the second percentage is less than the first percentage. The second percentage may range from about 10% to about 30%. The first percentage may range from about 20% to about 50%. The middle first semiconductor layer 104-2 may contain SiGe with the first percentage of Ge (or other percentage of Ge higher than the second percentage of Ge). The bottommost first semiconductor layer 104-3 formed of SiGe may have less Ge and more Si. For example, Ge may include about 10% to 30% of the bottommost first semiconductor layer 104-3 in molar ratio. By configuring the bottommost first semiconductor layer 104-3 having lower percentage of Ge, a less portion of the bottommost first semiconductor layer 104-3 will be removed during the subsequently-performed process (see FIG. 7).

Referring to FIG. 2 and with reference to FIG. 1, a portion of the stack of first semiconductor layers 104 and second semiconductor layers 106 along with the underlying portion of the semiconductor substrate 102′ may be removed to form trenches 100T, thereby defining a fin structure 100″ between adjacent trenches 100T. The fin structure 100″ may be formed by patterning the stack of first semiconductor layers 104 and second semiconductor layers 106 and the underlying semiconductor substrate 102′ by using, e.g., lithography and etching, or other suitable patterning processes. For example, a mask layer (not shown) is formed and patterned on the top of the stack, and the fin structure 100″ is formed by etching trenches 100T at portions of the stack of first semiconductor layers 104 and second semiconductor layers 106 and the underlying semiconductor substrate 102′ that are accessibly exposed by the mask layer. After forming the trenches 100T, the mask layer may be removed to reveal the topmost second semiconductor layer 106. The trenches 100T may be parallel strips (when viewed from the top) elongated along the Y-direction and distributed along the X-direction.

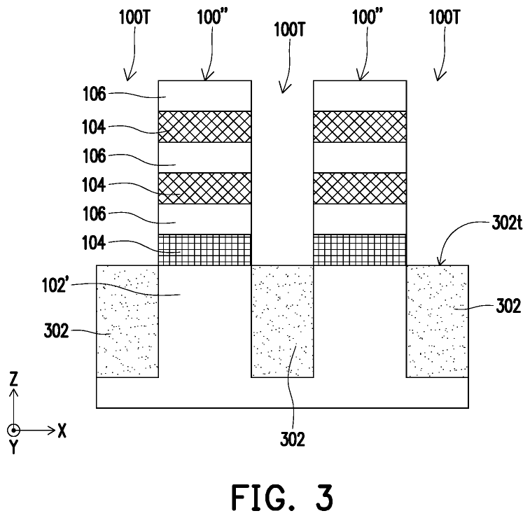

Referring to FIG. 3 and with reference to FIG. 2, a plurality of isolation structures 302, also referred to as shallow trench isolation (STI) structures, may be formed in lower portions of the trenches 100T. For example, the isolation structures 302 extend at opposing sides of a lower portion of the semiconductor substrate 102′. In some embodiments, each of the isolation structures 302 is disposed between adjacent two of the fin structures 100″ and covers a sidewall of a lower portion of the respective fin structure 100″. The top surface 302t of the respective isolation structure 302 may be a flat surface, a curved (e.g., convex or concave) surface, or a combination thereof. The isolation structures 302 may be formed of an insulation material (e.g., an oxide, a Si-based oxide (e.g., SiOC, SiOCN, or the like), a nitride, the like, any other suitable material, or combinations thereof) which may electrically isolate neighboring fin structures 100″ from each other. The isolation structures 302 may be formed by high-density plasma CVD, flow-able CVD, the like, a combination thereof, etc.

Referring to FIGS. 4A and 4B with reference to FIG. 3, a dummy gate structure 203 and a mask layer 204 overlying the dummy gate structure 203 may be formed on the fin structures 100″. For example, the dummy gate structure 203 includes a dummy dielectric layer 2031 formed on the fin structures 100″ and a dummy gate layer 2032 formed on the dummy dielectric layer 2031. In some embodiments, the dummy dielectric layer 2031 covers the top surfaces 302t of the isolation regions 302 and may extend between the dummy gate layer 2032 and the isolation regions 302. The dummy dielectric layer 2031 may include silicon oxide, silicon nitride, a combination thereof, or the like, and may be deposited or thermally grown according to acceptable techniques. The dummy gate layer 2032 may be a conductive or non-conductive material, and may be selected from a group including amorphous silicon, polysilicon, poly-crystalline silicon-germanium, metallic oxides, and metals, and may be formed by using physical vapor deposition (PVD), CVD, sputtering, or other suitable techniques.

The mask layer 204 formed on the dummy gate layer 2032 may be a single mask layer or include multiple sublayers formed of different materials including silicon nitride, silicon oxynitride, or the like. In the illustrated embodiment, the mask layer 204 includes a first mask sublayer 2041 overlying the dummy gate layer 2032 and a second mask sublayer 2042 overlying the first mask sublayer 2031. For example, a layer of mask material is initially formed and then patterned using acceptable lithography and etching techniques to form the mask layer 204. Next, the pattern of the mask layer 204 may be transferred to the underlying dummy gate and dielectric materials to form the dummy gate layer 2032 and the dummy dielectric layer 2031, respectively. For example, the dummy gate structure 203 has a lengthwise direction along the X-direction which is perpendicular to the lengthwise direction (e.g., the Y-direction) of the respective fin structure 100″.

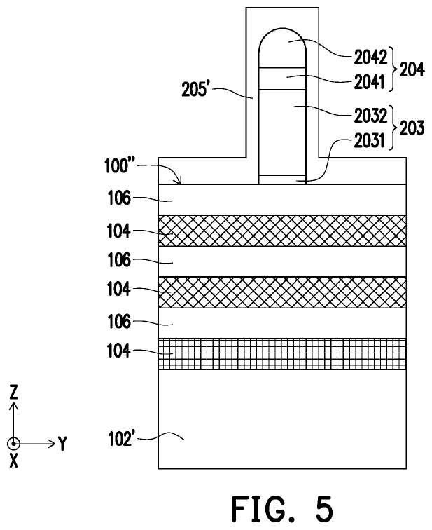

Referring to FIG. 5 and with reference to FIG. 4B, a gate spacer layer 205′ may be conformally formed on the dummy gate structure 203, the mask layer 204, and portions of the fin structure 100″ exposed by the dummy gate structure 203 and the mask layer 204. In the X-Z cross section (not shown), the gate spacer layer 205′ may further extend to cover sidewalls of the respective fin structure 100″. The gate spacer layer 205′ may be a single layer or may include multiple sublayers formed of different materials including silicon oxide, silicon nitride, silicon oxynitride, or the like. The gate spacer layer 205′ may be deposited by thermal oxidation or deposited by CVD, ALD, etc.

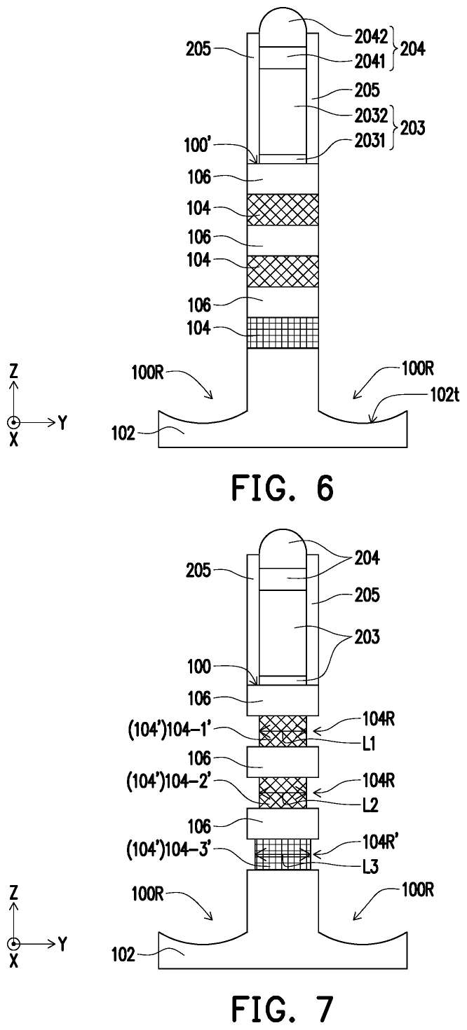

Referring to FIG. 6 and with reference to FIG. 5, a portion of the gate spacer layer 205′ covering an upper portion of the mask layer 204 and the top surface of the respective fin structure 100″ may be removed to form a gate spacer 205. For example, the gate spacer layer 205′ is partially removed using an etching process to form the gate spacer 205, where the gate spacer 205 may be disposed on the sidewall of the dummy gate structure 203 and may extend to partially (or fully) cover the sidewall of the mask layer 204. In some embodiments, the top surface and the upper sidewall of the second mask sublayer 2042 are exposed by the gate spacer 205. The gate spacer 205 may act to self-align subsequently-formed source/drain (S/D) regions, as well as to protect sidewalls of the respective fin structure 100″ during subsequent processing.

In some embodiments, a portion of the respective fin structure 100″ and a portion of the semiconductor substrate 102′ underlying the portion of the respective fin structure 100″ are removed to form recesses 100R and a respective etched fin structure 100′ between two adjacent recesses 100R. S/D regions will be subsequently formed in the recesses 100R, and the recesses 100R may be referred to as S/D recesses. The recesses 100R may be formed by etching the gate spacer layer 205′, the underlying fin structures 100″, and the underlying semiconductor substrate 102′ using etching processes, such as anisotropic etching, or the like. A single etching process or multiple etching processes may be employed. In some embodiments, outer sidewalls of the gate spacer 205 are substantially aligned with sidewalls of the etched fin structure 100′. The respective recess 100R may further extend into the underlying semiconductor substrate 102′ to form a semiconductor substrate 102 having exposed top surfaces 102t, where the top surfaces 102t may be a flat surface, a curved (e.g., concave) surface, or combinations thereof, depending on the etching process.

Referring to FIG. 7 and with reference to FIG. 6, portions of the first semiconductor layers 104 exposed by the recesses 100R may be removed in the lateral direction (e.g., the Y-direction) to form a respective etched fin structure 100 having etched first semiconductor layers 104′. The removal may be performed by, e.g., isotropic etching or the like. For example, the etchant of the selective etching process is chosen so that the portions of the first semiconductor layers 104 are removed to form lateral recesses (e.g., 104R and 104R′), while the second semiconductor layers 106 remain substantially intact after the etching. The respective etched first semiconductor layer 104′ may be laterally recessed from the sidewalls of the underlying (or overlying) second semiconductor layer 106. Although sidewalls of the etched first semiconductor layers 104′ adjacent to the lateral recesses 104R are illustrated as being straight in FIG. 7, the sidewalls of the etched first semiconductor layers 104′ may be tilted, concave, or convex.

With continued reference to FIG. 7, since the bottommost first semiconductor layer 104-3 may have lower percentage of Ge than the topmost first semiconductor layer 104-1 as mentioned in FIG. 1, the etched portion of the bottommost first semiconductor layer 104-3 is less than the etched portion of the topmost first semiconductor layer 104-1. For example, the lateral recess 104R surrounding the topmost first semiconductor layer 104-1′ may be wider than the lateral recess 104R′ surrounding the bottommost first semiconductor layer 104-3′. The bottommost first semiconductor layer 104-3′ may have a lateral dimension L3 greater than a lateral dimension L1 of the topmost first semiconductor layer 104-1′. In some embodiments, the middle first semiconductor layer 104-2′ may have a lateral dimension L2 less than the lateral dimension L3.

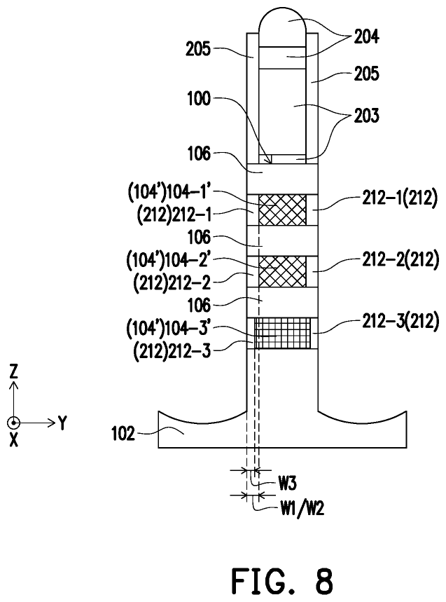

Referring to FIG. 8 and with reference to FIG. 7, inner spacers 212 (e.g., 212-1, 212-2, and 212-3) may be formed in the lateral recesses 104R and 104R′. For example, the inner spacers 212 are formed along the etched ends of each of the etched first semiconductor layers 104′ and along respective ends (along the Y-direction) of each of the etched first semiconductor layers 104′ and the second semiconductor layers 106. The inner spacers 212 may be formed of silicon nitride, silicon carbon-nitride, silicon-carbon-oxynitride, or any other type of dielectric material, and may be deposited using, e.g., a conformal deposition process and subsequent etching back to remove excess spacer material on the sidewalls of the etched fin structure 100 and on the exposed surface of the semiconductor substrate 102. In some embodiments, the inner spacers 212 are formed of a material different from the gate spacer 205. The gate spacer 205 may serve as an etch mask when removing the excess spacer material, and thus the outer sidewall of the gate spacer 205 may be substantially aligned with outer sidewalls of the underlying second semiconductor layers 106 and outer sidewalls of the inner spacers 212.

With continued reference to FIG. 8 and FIG. 7, the inner spacers (e.g., 212-1, 212-2, and 212-3) may each have sidewalls substantially aligned with one another. Since the bottommost first semiconductor layer 104-3′ having the greater lateral dimension L3 than the lateral dimensions L1 and L2 of the overlying first semiconductor layers (104-1′ and 104-2), the bottommost inner spacer 212-3 may have a thickness W3 less than a thickness W1 of the topmost inner spacer 212-1 and a thickness W2 of the middle inner spacer 212-2. For example, the difference between the thickness W1 and the thickness W3 ranges from about 0.5 nm to about 4.0 nm. In some embodiments, the thickness W1 of the topmost inner spacer 212-1 ranges from about 3 nm to about 14 nm. In some embodiments, the thickness W3 of the bottommost inner spacer 212-3 ranges from about 2 nm to about 10 nm. Other differences and thicknesses are within the contemplated scope of the disclosure. The thicknesses W1 and W2 may be substantially equal or may be different, depending on the lateral etching process variations.

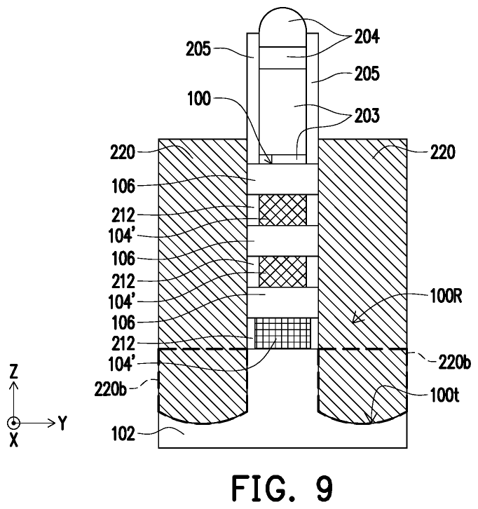

Referring to FIG. 9 and with reference to FIG. 8, epitaxial structures 220 may be epitaxially grown in the recesses 100R using a process such as CVD, ALD, MBE, or the like. The epitaxial structures 220 grown on the semiconductor substrate 102 may have a bottom surface conformally coupled to the exposed top surfaces 102t of the semiconductor substrate 102. In some embodiments where the semiconductor substrate 102 has a concave top surface, the bottom surface of the respective epitaxial structure 220 may be a convex surface corresponding to the exposed top surfaces 102t. Although the upper surfaces of the epitaxial structures 220 are illustrated as planar surfaces in the Y-Z cross section, it should be understood that in the perspective view, the upper surfaces of the epitaxial structures 220 have facets which expand laterally outward along the Y-direction beyond the sidewalls of the dummy gate structures 203. In some embodiments, the epitaxial structures 220 are coupled to the outer sidewalls of the second semiconductor layers 106 and the inner spacers 212 along the Y-direction. Each dummy gate structure 203 may be disposed between respective neighboring pairs of the epitaxial structures 220. The gate spacer 205 may be used to separate the epitaxial structures 220 from the dummy gate structure 203 by a lateral distance so that the epitaxial structures 220 do not short out with subsequently-formed gate structures.

Each epitaxial structure 220 may include silicon germanium, indium arsenide, indium gallium arsenide, indium antimonide, germanium arsenide, germanium antimonide, indium aluminum phosphide, indium phosphide, any other suitable material, or combinations thereof. The epitaxial structures 220 may be doped with a conductive dopant to form S/D regions. For example, the S/D dopant may be formed by in-situ epitaxially growth, ion implantation, solid phase diffusion, a combination thereof, etc., where the ion implantation process or the solid phase diffusion process may be processed after epitaxially growth or after the etching of FIG. 12. It should be noted that S/D region(s) may refer to a source or a drain, individually or collectively dependent upon the context. The terms “epitaxial structures” and “S/D regions” are used interchangeably herein. The structure shown herein may be in the n-type region (e.g., the NMOS region) or the p-type region (e.g., the PMOS region). In some embodiments, the dopant of the epitaxial structures 220 grown in the n-type region (not individually shown) may be donor-type species, such as phosphorus, arsenic, antimony for silicon-based transistor. In some embodiments, the dopant of the epitaxial structures 220 grown in the p-type region (not individually shown) may be acceptor-type species, such as boron, aluminum, gallium for silicon-based transistor.

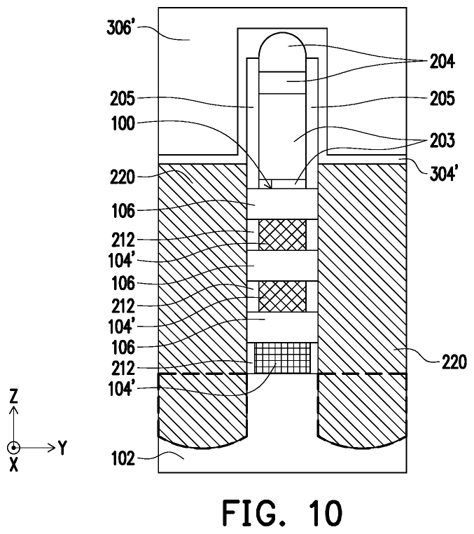

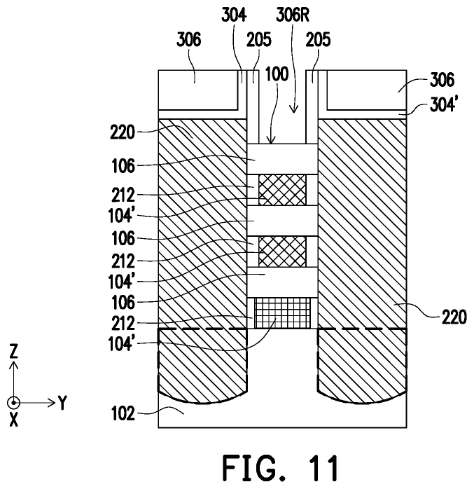

With continued reference to FIG. 9, the respective epitaxial structure 220 may have different doping levels. For example, the respective epitaxial structure 220 includes a bottom region 220b overlying the semiconductor substrate 102 and laterally adjacent to the raised portion of the semiconductor substrate 102. The bottom region 220b may be an undoped region (or substantially dopant-free region). The other region of the respective epitaxial structure 220 overlying the bottom region 220b may be doped with a higher doping concentration than the bottom region 220b. Alternatively, the bottom region 220b is omitted. The bottoms region 220b in FIG. 9 and the following FIGS. 10-14 are illustrated in the dashed lines to indicate they may or may not exist.

Referring to FIG. 10 and with reference to FIG. 9, a first interlayer dielectric (ILD) material layer 306′ may be formed over the structure illustrated in FIG. 9. The first ILD material layer 306′ may be formed of a dielectric material including phosphosilicate glass (PSG), borosilicate glass (BSG), boron-doped phosphosilicate glass (BPSG), undoped silicate glass (USG), or the like, and may be deposited by any suitable method, such as CVD, plasma-enhanced CVD (PECVD), or the like. In some embodiments, an etch stop material layer 304′ is disposed between the first ILD material layer 306′ and the epitaxial structures 220, the mask layer 204, and the gate spacer 205. The etch stop material layer 304′ may include a dielectric material (e.g., silicon nitride, silicon oxide, silicon oxynitride, or the like), and may have a different etch rate than the material of the overlying first ILD material layer 306′.

Referring to FIG. 11 and with reference to FIG. 10, one or more removal processes may be performed to form a first ILD layer 306, the etch stop layer 304 lining the first ILD layer 306, and a recess 306R accessibly revealing the topmost one of the second semiconductor layers 106 of the respective etched fin structure 100. For example, the removal processes includes a planarization process performed on the first ILD material layer 306′. The planarization process may include CMP, grinding, etching, combinations thereof, or the like. During the planarization process, the mask layer 204 may be partially (or fully) removed. In some embodiments, the gate spacer 205 is also planarized during the planarization process. In some embodiments, one or more etching process may be performed after the planarization to remove the rest portion of the mask layer 204 (if exist) and the underlying dummy gate structure 203 so as to form the recess 306R. For example, reaction gas(es) may be used to selectively etch the dummy structure 203 at a faster rate than the first ILD material layer 306′, the etch stop material layer 304′, or the gate spacer 205.

Referring to FIG. 12 and with reference to FIG. 11, the etched first semiconductor layers 104′ may be removed by etching (e.g., isotropic etching or the like) to form recesses 104S (e.g., 104-1S, 104-2S, and 104-3S). For example, using etchants which are selective to the materials of the etched first semiconductor layers 104′, while the second semiconductor layers 106, the first ILD layer 306, the etch stop layer 304, the gate spacer 205, and the inner spacers 212 remain relatively un-etched as compared to the etched first semiconductor layers 104′. During the removal process, the first ILD layer 306 and the etch stop layer 304 may protect the epitaxial structures 220. In some embodiments, after the removal of the etched first semiconductor layers 104′, respective bottom and top surfaces of each second semiconductor layers 106 and the top surface of the semiconductor substrate 102 may be exposed by the recesses 104S. Since the bottommost first semiconductor layer 104-3′ has the greater lateral dimension L3 (see FIG. 7), the bottommost recess 104-3S formed by removing the bottommost first semiconductor layer 104-3′ may have a recess size greater than recess sizes of the overlying recesses 104-1S and 104-2S which are respectively formed by removing the topmost first semiconductor layers 104-1′ and the middle first semiconductor layers 104-2′.

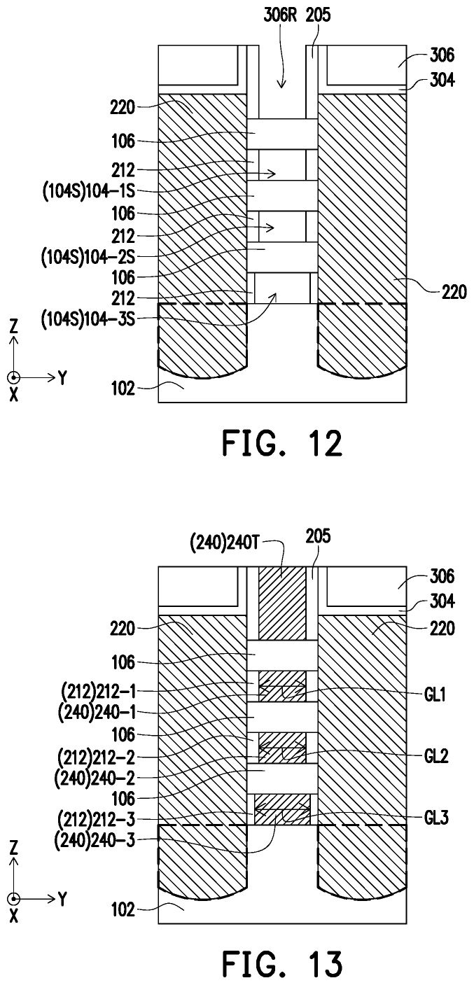

Referring to FIG. 13 and with reference to FIG. 12, a gate structure 240 may be formed around the second semiconductor layers 106 and fill the recesses 306R and 104S. The gate structure 240 may include a plurality of gate sections (e.g., 240T, 240-1, 240-2, and 240-3) abutted to each other along the Z-direction in the X-Z plane. Each of the gate sections may extend not only along a horizontal plane (e.g., the X-Y plane), but also along a vertical direction (e.g., the Z-direction), and thus two adjacent ones of the gate sections may adjoin together to wrap around a corresponding one of the second semiconductor layers 106, where the second semiconductor layers 106 (also referred to as semiconductor nanosheets or channel layers) function as channel regions.

The gate structure 240 may include a gate dielectric layer (not individually shown), an interfacial layer (not individually shown) formed between each channel layer 106 and the gate dielectric layer, and a gate metal layer (not individually shown) wrapping around each channel layer 106 with the gate dielectric layer disposed therebetween. The gate dielectric layer may be one or more high-k dielectric material(s). The gate metal layer may include a stack of multiple metal materials. For example, one or more work function sublayers are interposed between the gate dielectric layer and the gate metal layer, where the work function sublayers may be formed separately for the n-type FET and the p-type FET which may use different metal layers. In some embodiments, excess materials of the gate structure 240 may be removed by a planarization process, so that the top surface of the topmost gate structure 240 is substantially leveled (e.g., coplanar) with top surfaces of the first ILD layer 306 and the etch stop layer 304, within process variations.

With continued reference to FIG. 13, in the Y-Z cross section, the bottommost gate section 240-3 is laterally surrounded by the bottommost inner spacer 212-3 may have a lateral dimension (also referred to as the bottommost gate length) GL3 greater than a lateral dimension (also referred to as the topmost gate length) GL1 of the topmost gate section 240-1 laterally surrounded by the topmost inner spacer 212-1. For example, a ratio of the lateral dimension GL3 to the lateral dimension GL1 ranges from about 1.0 to about 2.0. Although other ratios are within the contemplated scope of the disclosure. In some embodiments, the lateral dimension GL3 is greater than a lateral dimension GL2 of the middle gate section 240-2 laterally surrounded by the middle inner spacer 212-2. The lateral dimensions GL1 and GL2 may be substantially equal or may be different, depending on the thicknesses of the inner spacers 212-1 and 212-2 and the process variations.

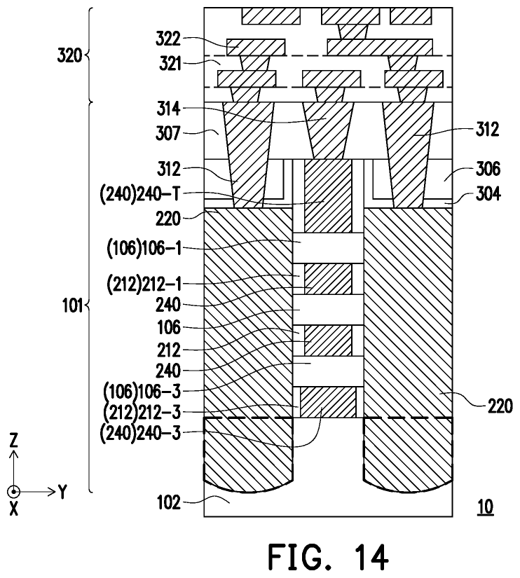

Referring to FIG. 14 and with reference to FIG. 13, a second ILD layer 307 may be formed on the first ILD layer 306. The second ILD layer 307 may be formed of a dielectric material such as PSG, BSG, BPSG, USG, or the like, and may be deposited by any suitable method, such as CVD, PECVD, or the like. In some embodiments, S/D contacts 312 are formed to extend through the second ILD layer 307 and the underlying first ILD layer 306 so as to be electrically coupled to the epitaxial structures 220. A gate contact 314 may be formed to extend through the second ILD layer 307 so as to be electrically coupled to the topmost gate section 240T of the gate structure 240. In some embodiments, a planarization process is performed to level the top surfaces of the S/D contacts 312 and the gate contact 314.

In some embodiments, a front-side interconnect structure 320 including interconnect wirings 322 formed in an interconnect dielectric layer 321 may be formed on the second ILD layer 307, the S/D contacts 312, and the gate contact 314. The front-side interconnect structure 320 may be formed by back end of line (BEOL) processes and may be referred to as a BEOL interconnect structure. The material of the interconnect dielectric layer 321 may include a low-k dielectric material, an extra low-k (ELK) dielectric material, or the like. The interconnect wirings 322 may include conductive pads, conductive lines, and conductive vias interconnecting the layers of conductive lines, and may be formed through any acceptable process, such as a damascene process, a dual damascene process, or the like. For example, the conductive vias may extend through the interconnect dielectric layer 321 to provide vertical connections between layers of the conductive lines, and the bottommost conductive vias of the interconnect wirings 322 may be in physical and electrical contact with the S/D contacts 312 and the gate contact 314. The front-side interconnect structure 320 may be electrically coupled to the epitaxial structures 220 and the gate structure 240 through the S/D contacts 312 and the gate contact 314, respectively, to form functional circuits.

With continued reference to FIG. 14, a semiconductor device 10 includes a device layer 101 formed in/on the semiconductor substrate 102 and the front-side interconnect structure 320 formed on the device layer 101. The device layer 101 may include a plurality of active devices (e.g., transistors), and the respective active device may include the epitaxial structure 220 (e.g., S/D regions), the second semiconductor layers 106 (e.g., the channel regions/layers), and the gate structures 240. The structure illustrated in FIG. 14 may be in the n-type (e.g., NMOS) region or the p-type (e.g., PMOS) region. Although the device layer 101 shown herein is described as including nano-FETs, other embodiments may include device layers including different types of transistors, such as planar FETs, FinFETs, thin film transistors, or the like. The semiconductor device 10 may be a portion of a device wafer having a plurality of die regions. The device wafer may be singulated to separate a die from one another, and then the die may be packaged to form an IC package. The die may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a MEMS controller (e.g., application specific integrated circuit (ASIC)), a signal processing die (e.g., digital signal processing (DSP) die), a front-end die (e.g., analog front-end (AFE) dies), the like, or combinations thereof.

Still referring to FIG. 14, the bottommost inner spacer 212-3 extending along sidewalls of the bottommost gate section 240-3 may be thinner than the overlying inner spacers 212, and the bottommost gate section 240-3 laterally covered by the bottommost inner spacer 212-3 may have a gate length longer than the overlying gate sections. It should be appreciated that the thickness of the inner spacer 212 may affect the dimensions of overlapping and underlapping regions of the channel layer. For example, the overlapping region of the bottommost channel layer 160-3 is a region directly on the bottommost gate section 240-3, and the underlapping region of the bottommost channel layer 160-3 is a region directly on the bottommost inner spacer 212-3. By configuring the thinner bottommost inner spacer 212-3, the wider bottommost gate section 240-3 may be formed, the overlapping region may be increased, and the underlapping region may be decreased, thereby reducing resistance of the bottommost channel layer 106-3.

It has been observed that for the semiconductor device having the inner spacers with the same thickness at each level, the bottommost channel region has higher resistance than the topmost channel regions due to the longer gate-to-S/D current path for the bottommost channel region and less junction overlapping by lower doping concentration. For example, the lower section of the S/D region laterally adjacent to the bottommost channel region has a lower doping concentration than the top section of the S/D region laterally adjacent to the topmost channel regions. By configuring the thinner bottommost inner spacer 212-3, the gate length may be increased and gate-junction overlapping may be improved. This in turn enhances the performance of the semiconductor device 10.

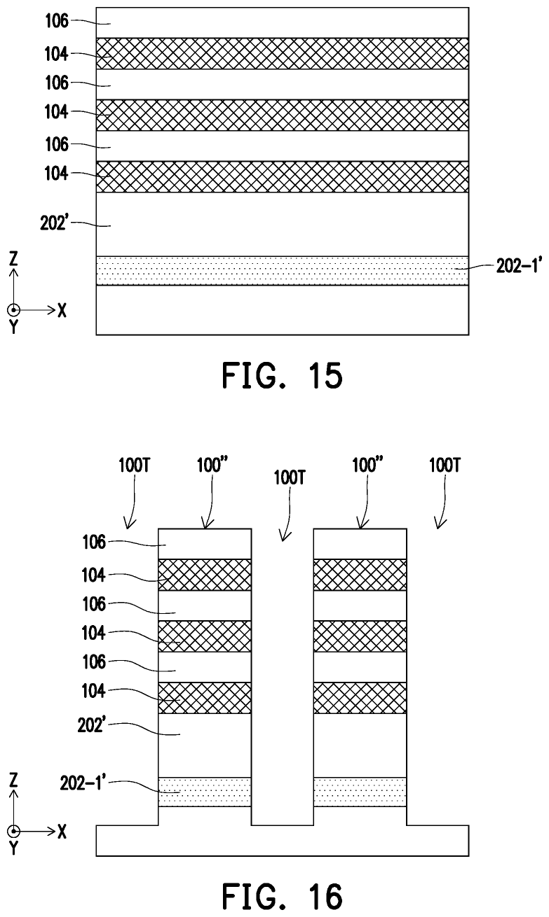

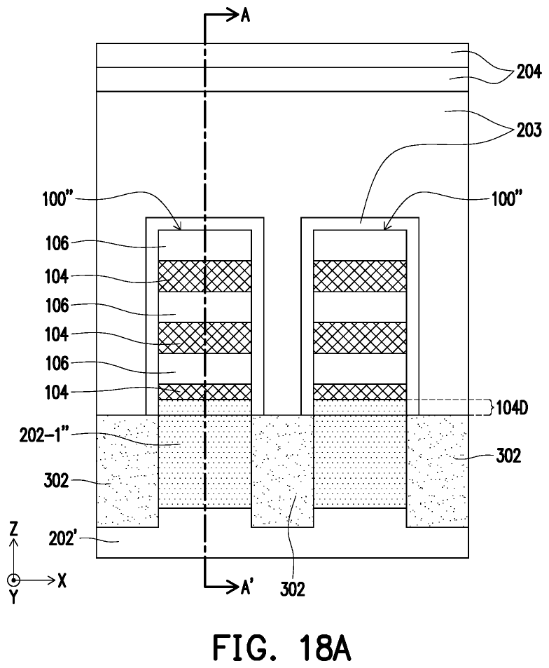

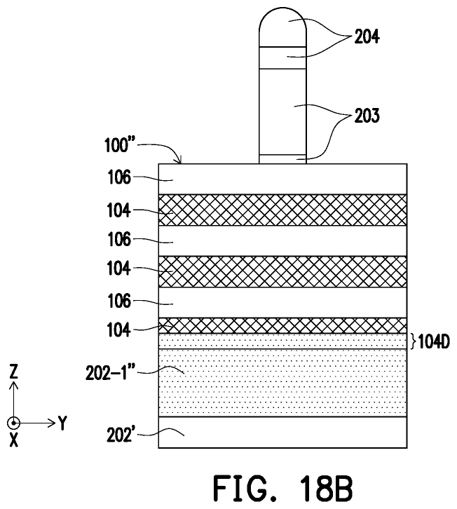

FIGS. 15-22 illustrate schematic cross-sectional views of intermediate steps during a process for forming a semiconductor device, in accordance with some embodiments. It should be noted that FIGS. 15-18A are cross-sectional views of the structure taken at the X-Z plane, FIG. 18B is a cross-sectional view of the structure illustrated in FIG. 18A taken along the line A-A′, and FIGS. 18B and 19-22 are cross-sectional views taken at the Y-Z plane and illustrating the following steps of forming a semiconductor device. Unless specified otherwise, like reference numerals in this embodiment represent like components in the embodiment shown in FIGS. 1-14 formed by like processes. Accordingly, the process steps and applicable materials may not be repeated herein. In addition, although FIGS. 15-22 are described as a series of acts, these acts are not limiting in that the order of the acts can be altered in other embodiments, and the methods disclosed are also applicable to other structures. Alternatively, some acts that are illustrated and/or described may be omitted in whole or in part.

Referring to FIG. 15 and with reference to FIG. 1, the structure shown in FIG. 15 is similar to the structure shown in FIG. 1, and the difference therebetween includes that the semiconductor substrate 202′ includes a doped layer 202-1′ and the bottommost first semiconductor layer is substantially that same as the overlying first semiconductor layers 104. The material of the semiconductor substrate 202′ may be similar to that of the semiconductor substrate 102′. In some embodiments, the doped layer 202-1′ is an anti-punch through (APT) doped layer. For example, the ion implantation is performed on the semiconductor substrate to form the doped layer 202-1′. Other suitable methods may be used to form the doped layer 202-1′ in the semiconductor substrate 202′. In some embodiments, the ion implantation of dopants (e.g., dopants used for APT implants) includes phosphorus, boron, carbon, arsenic, gallium, antimony, etc. In some embodiments, the doped layer 202-1′ in the n-type region (not shown) has dopant species and/or doping concentration different from the doped layer 202-1′ in the p-type region (not shown). In some embodiments, the doped layers 202-1′ in both of the n-type region and the p-type region (not shown) have the same dopant species and/or doping concentration.

Referring to FIG. 16 and with reference to FIG. 15 and FIG. 2, a portion of the stack of first semiconductor layers 104 and second semiconductor layers 106 along with the underlying portion of the semiconductor substrate 202′ may be removed to form the trenches 100T, thereby defining the fin structure 100″ between adjacent the trenches 100T. The removal process may be similar to the process described in FIG. 2.

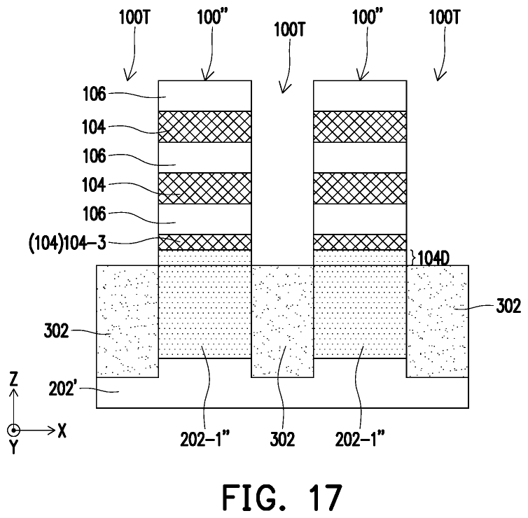

Referring to FIG. 17 and with reference to FIG. 16 and FIG. 3, the isolation structure 302 may be formed in lower portions of the trenches 100T as described in FIG. 3. In some embodiments, during the formation of the isolation structure 302, an anneal process may be performed once the insulation material is deposited. The anneal temperature may cause dopants in the doped layer 202-1′ diffusion. In some embodiments, the dopants from the doped layer 202-1′ are diffused into the bottommost first semiconductor layer 104-3 during (or after) forming the isolation structure 302. In some embodiments where the doped layer 202-1′ contains boron atoms, the boron atoms in the doped layer 202-1′ diffuse into the bottommost first semiconductor layer 104-3 to form a diffused region 104D in the bottommost first semiconductor layer 104-3. In some embodiments, the diffused region 104D is disposed at the bottom section of the bottommost first semiconductor layer 104-3 most proximate from the semiconductor substrate 202′, and the top section of the bottommost first semiconductor layer 104-3 most distal from the semiconductor substrate 202′ may remain substantially dopant-free. In some embodiments, the diffused region 104D extends from the bottom to the top of the bottommost first semiconductor layer 104-3. For example, the diffused region 104D occupies the entire bottommost first semiconductor layer 104-3. The diffused area in the bottommost first semiconductor layer 104-3 may vary depending on process variations.

Referring to FIGS. 18A-18B and with reference to FIGS. 4A-4B, the dummy gate structure 203 and the mask layer 204 may be sequentially formed on the fin structures 100″. The materials and the forming processes of the dummy gate structure 203 and the mask layer 204 are similar to those of the dummy gate structure 203 and the mask layer 204 described in FIG. 4A-4B.

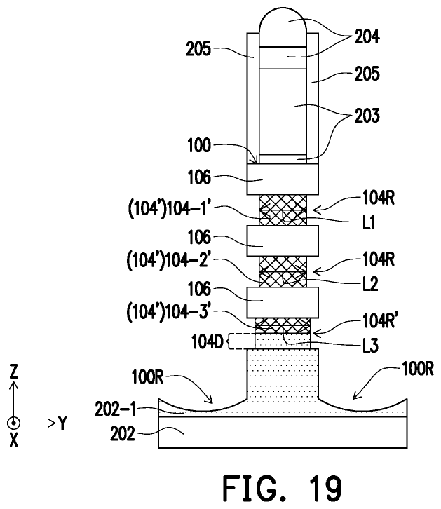

Referring to FIG. 19 and with reference to FIG. 18B and FIGS. 5-7, the gate spacer 205 may be conformally formed on the dummy gate structure 203, the mask layer 204, and the top of the fin structure 100″. Next, the respective fin structure 100″ and the semiconductor substrate 102′ may be partially removed to form the recesses 100R. After forming the recesses 100R, a portion of the doped layer may still remain, and thus the semiconductor substrate 202 with the recessed doped layer 202-1 is provided. Next, the first semiconductor layers 104 exposed by the recesses 100R may be removed in the lateral direction (e.g., the Y-direction) to form the respective etched fin structure 100 having the etched first semiconductor layers 104′. The forming processes of the gate spacer 205, the recesses 100R, and the etched first semiconductor layers 104′ may be similar to the processes described in FIGS. 5-7.

With a selective etching process, the diffused region 104D in the bottommost first semiconductor layer 104-3′ may slow down the lateral etching. For example, the bottommost first semiconductor layer 104-3′ with the diffused region 104D is etched more slowly than the first semiconductor layers without the diffused region (e.g., 104-1′ and 104-2′). The difference in dimensions of the lateral recesses 104R and 104R′ may be results of difference in etch rates. For example, the dimension of the lateral recess 104R′ corresponding to the bottommost first semiconductor layer 104-3′ is less than that of the lateral recess 104R corresponding to the topmost first semiconductor layer 104-1′. The smaller dimension of the lateral recess 104R′ may result in the larger size of the bottommost first semiconductor layer 104-3′ remained. For example, the lateral dimension L3 of the bottommost first semiconductor layer 104-3′ is greater than the lateral dimension L1 of the topmost first semiconductor layer 104-1′ and also greater than the lateral dimension L2 of the middle first semiconductor layer 104-2′. The bottommost first semiconductor layer 104-3′ may have a tilted (or curved) sidewall (not illustrated) after the lateral etching, since a region of the bottommost first semiconductor layer 104-3′ that is substantially free of dopants may be etched faster than the diffused region 104D.

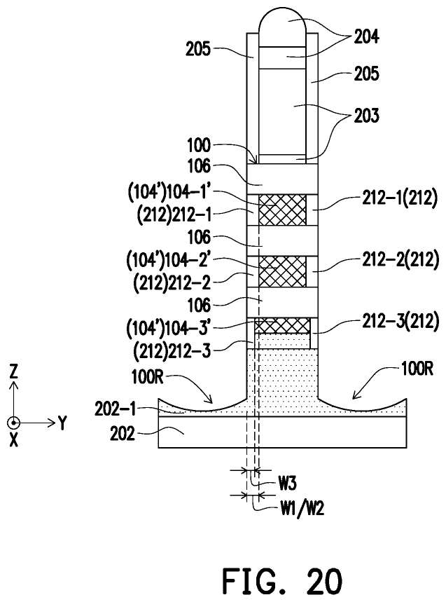

Referring to FIG. 20 and with reference to FIG. 19 and FIG. 8, the inner spacers 212 (e.g., 212-1, 212-2, and 212-3) may be formed in the lateral recesses 104R and 104R′. The material and the forming process of the inner spacers 212 may be similar to those of the inner spacers described in FIG. 8. The bottommost inner spacer 212-3 may have the thickness W3 less than the thickness W1 of the topmost inner spacer 212-1 and also less than the thickness W2 of the middle inner spacer 212-2.

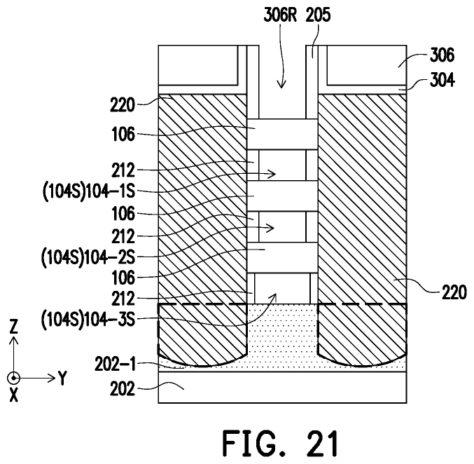

Referring to FIG. 21 and with reference to FIG. 20 and FIGS. 9-12, the epitaxial structures 220 may be epitaxially grown in the recesses 100R. The epitaxial structures 220 grown on the semiconductor substrate 102 may be in physical contact with the recessed doped layer 202-1. As mentioned in FIG. 9, the respective epitaxial structure 220 may have different doping levels and may include an undoped region at the bottom, where the undoped region is illustrated in the dashed lines to indicate it may or may not exist. Next, the first ILD layer 306, the etch stop layer 304, and the recess 306R accessibly revealing the topmost one of the second semiconductor layers 106 of the respective etched fin structure 100 may be formed. The materials and the formation processes may be similar to the materials and the processes described in FIGS. 10-11. Next, the etched first semiconductor layers 104′ may be removed to form the recesses 104S (e.g., 104-1S, 104-2S, and 104-3S). The process may be similar to the process described in FIG. 12.

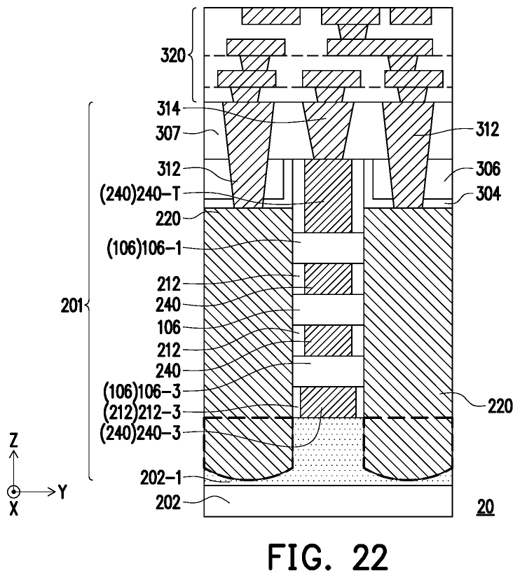

Referring to FIG. 22 and with reference to FIG. 21 and FIGS. 13-14, the gate structure 240 may be formed around the second semiconductor layers 106 and fill the recesses 306R and 104S. The material and the forming process of the gate structure 240 may be similar to those of the gate structure 240 described in FIG. 13. Next, the second ILD layer 307, the S/D contacts 312 extending through the second ILD layer 307 and the first ILD layer 306 to be coupled to the epitaxial structures 220, and the gate contact 314 extending through the second ILD layer 307 to be coupled to the topmost gate section 240T of the gate structure 240 may be formed. The front-side interconnect structure 320 may then be formed on the second ILD layer 307, the S/D contacts 312, and the gate contact 314. The materials and the forming processes of these features may be similar to those of the corresponding features described in FIG. 14.

With continued reference to FIG. 22 and FIG. 14, a semiconductor device 20 including a device layer 201 formed in/on the semiconductor substrate 202 and the front-side interconnect structure 320 formed on the device layer 201 is provided. The difference between the semiconductor device 20 and the semiconductor device 10 illustrated in FIG. 14 lies in that the semiconductor substrate 202 of the semiconductor device 20 includes the recessed doped layer 202-1 physically coupled to the bottom surfaces of the S/D regions 220, the bottommost inner spacer 212-3, and the bottommost gate section 240-3. Since the bottommost inner spacer 212-3 is thinner than the overlying inner spacers 212, the bottommost gate section 240-3 laterally covered by the bottommost inner spacer 212-3 may have a longer gate length than the overlying gate sections. By performing the annealing to allow the dopants in the doped layer of the semiconductor substrate diffused into the bottommost first semiconductor layer so as to form the diffused region, the lateral recessing of the bottommost first semiconductor layer may be slowed down such that the bottommost inner spacer formed around the bottommost first semiconductor layer may have a smaller thickness as compared to the thickness of the overlying inner spacers. By configuring the thinner bottommost inner spacer 212-3, the gate length of the bottommost gate section 240-3 may be increased and gate-junction overlapping may be improved. This in turn enhances the performance of the semiconductor device 20.

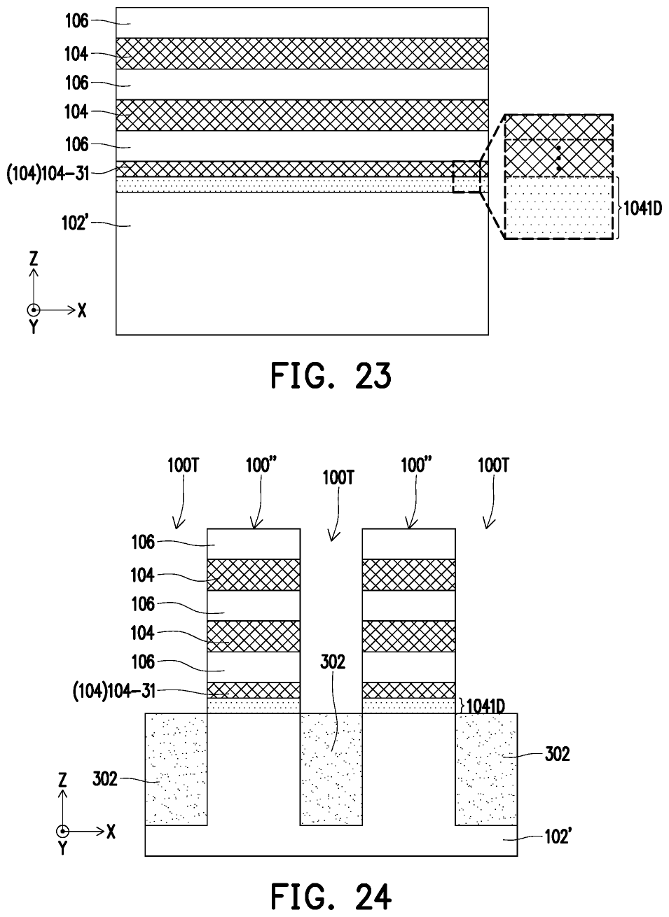

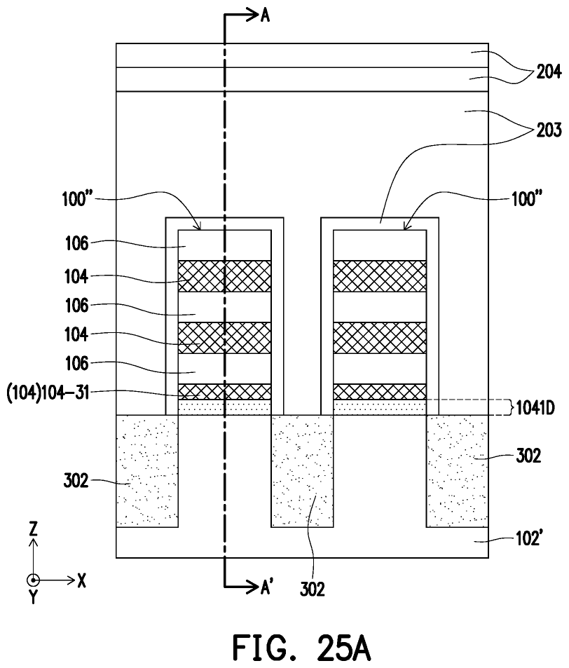

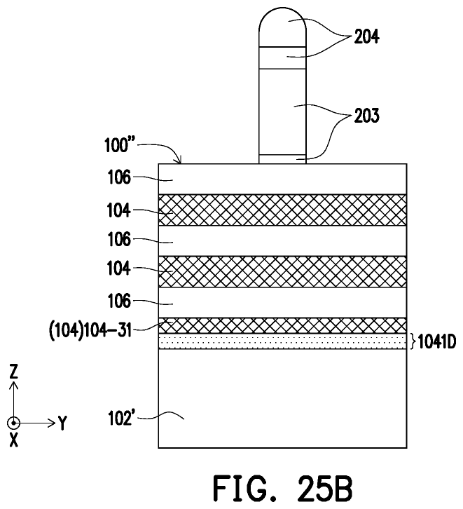

FIGS. 23-29 illustrate schematic cross-sectional views of intermediate steps during a process for forming a semiconductor device, in accordance with some embodiments. It should be noted that FIGS. 23-25A are cross-sectional views of the structure taken at the X-Z plane, FIG. 25B is a cross-sectional view of the structure illustrated in FIG. 25A taken along the line A-A′, and FIGS. 25B and 26-29 are cross-sectional views taken at the Y-Z plane and illustrating the following steps of forming a semiconductor device. Unless specified otherwise, like reference numerals in this embodiment represent like components in the embodiment shown in FIGS. 1-22 formed by like processes. Accordingly, the process steps and applicable materials may not be repeated herein. In addition, although FIGS. 23-29 are described as a series of acts, these acts are not limiting in that the order of the acts can be altered in other embodiments, and the methods disclosed are also applicable to other structures. Alternatively, some acts that are illustrated and/or described may be omitted in whole or in part.

Referring to FIG. 23 and with reference to FIG. 1, the structure shown in FIG. 23 is similar to the structure shown in FIG. 1, except for the bottommost first semiconductor layer 104-31. The bottommost first semiconductor layer 104-31 may include a doped region 1041D. For example, the bottommost first semiconductor layer 104-31 and the overlying first semiconductor layer 104 may have the same material (or composition), and the ion implantation is performed to form the doped region 1041D in the bottommost first semiconductor layer 104-31. For example, a bottom section of the bottommost first semiconductor layer 104-31 is lightly doped to form the doped region 1041D, where the doped region 1041D is viewed as a lightly doped region. In some embodiments, the bottommost first semiconductor layer 104-31 is a single layer including the doped region 1041D at the bottom. In some embodiments (as shown in the enlarged view), the bottommost first semiconductor layer 104-31 includes different doping levels. In some embodiments (as shown in the enlarged view), the bottommost first semiconductor layer 104-31 includes a plurality of sublayers, and the sublayers may include different percentages of Ge (or different materials/compositions) to migrate dopant diffusion into the bottommost second semiconductor layer 106, where at least the bottommost one of the sublayers is doped to form the doped region 1041D. For example, the bottommost first semiconductor layer 104-31 includes the dopants in the doped region 1041D that enable the etch rate of the bottommost first semiconductor layer to be slowed down. In some embodiments, dopants in the doped region 1041D include phosphorus, boron, carbon, arsenic, gallium, antimony, etc.

The first semiconductor layers 104 overlying the bottommost first semiconductor layer 104-31 may be undoped or substantially dopant-free. In some embodiments, one or more first semiconductor layers 104 overlying the bottommost first semiconductor layer 104-31 may have a different doping concentration or may have different dopants than the bottommost first semiconductor layer 104-31. For example, the first semiconductor layers 104 overlying the bottommost first semiconductor layer 104-31 include the dopants that enable the etch rate of the overlying first semiconductor layers 104 to be faster than the bottommost first semiconductor layer 104-31.

Referring to FIG. 24 and with reference to FIG. 23 and FIGS. 2-3 or FIGS. 16-17, a portion of the stack of first semiconductor layers 104 and second semiconductor layers 106 along with the underlying portion of the semiconductor substrate 102′ may be removed to form the trenches 100T, thereby defining the fin structure 100″. The removal process may be similar to the process described in FIG. 2. Next, the isolation structure 302 may be formed in lower portions of the trenches 100T as described in FIG. 3. In some embodiments, during the formation of the isolation structure 302, an anneal process may be performed once the insulation material is deposited. The anneal temperature may cause dopants in the doped region 1041D diffusion. By configuring the bottommost second semiconductor layer 106 having multiple sublayers, the doped region 1041D may be confined. In alternative embodiments, the doped region 1041D expands during (or after) forming the isolation structure 302. For example, the doped region 1041D occupies the entire bottommost first semiconductor layer 104-31.

Referring to FIGS. 25A-25B and with reference to FIGS. 4A-4B, the dummy gate structure 203 and the mask layer 204 may be sequentially formed on the fin structures 100″. The materials and the forming processes of the dummy gate structure 203 and the mask layer 204 are similar to those of the dummy gate structure 203 and the mask layer 204 described in FIG. 4A-4B.

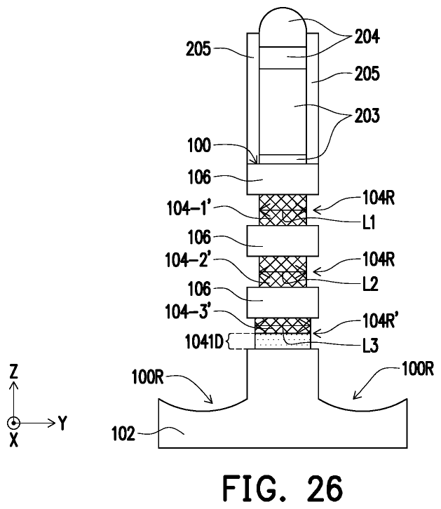

Referring to FIG. 26 and with reference to FIG. 25B and FIGS. 5-7, the gate spacer 205 may be conformally formed on the dummy gate structure 203, the mask layer 204, and the top of the fin structure 100″. Next, the respective fin structure 100″ and the semiconductor substrate 102′ may be partially removed to form the recesses 100R. Next, the first semiconductor layers 104 exposed by the recesses 100R may be removed in the lateral direction (e.g., the Y-direction) to form the respective etched fin structure 100 having etched first semiconductor layers 104′. The forming processes of the gate spacer 205, the recesses 100R, and the etched first semiconductor layers 104′ may be similar to the processes described in FIGS. 5-7. After forming the etched first semiconductor layers 104′, the doped region 1041D may still remain in the bottommost first semiconductor layer 104-3′.

With a selective etching process, the doped region 1041D in the bottommost first semiconductor layer 104-3′ may slow down lateral etching. For example, the bottommost first semiconductor layer 104-3′ having the doped region 1041D is etched more slowly than the first semiconductor layers without the doped region (e.g., 104-1′ and 104-2′). The difference in etch rates may result in the difference in dimensions of the lateral recesses 104R and 104R′. For example, the dimension of the lateral recess 104R′ corresponding to the bottommost first semiconductor layer 104-3′ is less than that of the lateral recess 104R corresponding to the topmost first semiconductor layer 104-1′. The smaller dimension of the lateral recess 104R′ may result in the larger size of the bottommost first semiconductor layer 104-3′ remained. For example, the lateral dimension L3 of the bottommost first semiconductor layer 104-3′ is greater than the lateral dimension L1 of the topmost first semiconductor layer 104-1′ and also greater than the lateral dimension L2 of the middle first semiconductor layer 104-2′.

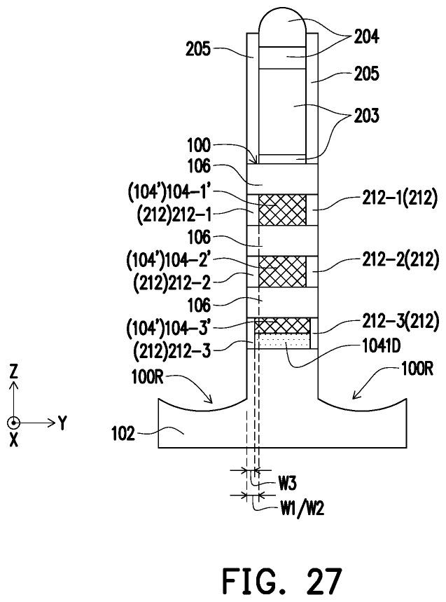

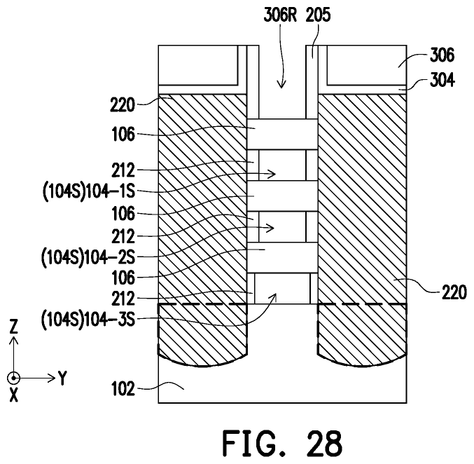

Referring to FIG. 27 and with reference to FIG. 26 and FIG. 8, the inner spacers 212 (e.g., 212-1, 212-2, and 212-3) may be formed in the lateral recesses 104R and 104R′. The material and the forming process of the inner spacers 212 may be similar to those of the inner spacers described in FIG. 8. Since the bottommost first semiconductor layer 104-3′ having the lateral dimension L3 greater than the lateral dimensions L1 and L2 of the overlying first semiconductor layers (104-1′ and 104-2′), the bottommost inner spacer 212-3 may have the thickness W3 less than the thickness W1 of the topmost inner spacer 212-1 and also less than the thickness W2 of the middle inner spacer 212-2.

Referring to FIG. 28 and with reference to FIG. 27 and FIGS. 9-12, the epitaxial structures 220 may be epitaxially grown in the recesses 100R. As mentioned in FIG. 9, the respective epitaxial structure 220 may have different doping levels and may include an undoped region at the bottom, where the undoped regions are illustrated in the dashed lines to indicate they may or may not exist. Next, the first ILD layer 306, the etch stop layer 304, and the recess 306R accessibly revealing the topmost one of the second semiconductor layers 106 of the respective etched fin structure 100 may be formed. The materials and the formation processes may be similar to the materials and the processes described in FIGS. 10-11. Next, the etched first semiconductor layers 104′ may be removed to form the recesses 104S (e.g., 104-1S, 104-2S, and 104-3S). The process may be similar to the process described in FIG. 12.

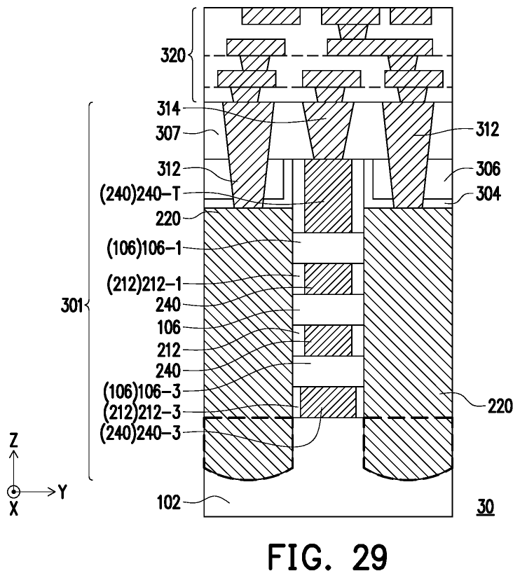

Referring to FIG. 29 and with reference to FIG. 28 and FIGS. 13-14, the gate structure 240 may be formed around the second semiconductor layers 106 and fill the recesses 306R and 104S. The material and the forming process of the gate structure 240 may be similar to those of the gate structure 240 described in FIG. 13. Next, the second ILD layer 307, the S/D contacts 312 extending through the second ILD layer 307 and the first ILD layer 306 to be coupled to the epitaxial structures 220, and the gate contact 314 extending through the second ILD layer 307 to be coupled to the topmost gate section 240T of the gate structure 240 may be formed. The front-side interconnect structure 320 may be formed on the second ILD layer 307, the S/D contacts 312, and the gate contact 314. The materials and the forming process of these features may be similar to those of the corresponding features described in FIG. 14.

With continued reference to FIG. 29 and FIG. 14, a semiconductor device 30 including a device layer 301 formed in/on the semiconductor substrate 102 and the front-side interconnect structure 320 formed on the device layer 101 is provided. The semiconductor device 30 is similar to the semiconductor device 10 illustrated in FIG. 14, except for the forming method of the thinner bottommost inner spacer and the longer bottommost gate section. In the illustrated embodiment, by configuring the doped region in the bottommost first semiconductor layer, the lateral recessing of the bottommost first semiconductor layer may be slowed down such that the bottommost inner spacer formed around the bottommost first semiconductor layer may have a smaller thickness as compared to the thickness of the overlying inner spacers. By configuring the thinner bottommost inner spacer 212-3, the gate length of the bottommost gate section 240-3 may be increased and gate-junction overlapping may be improved. This in turn enhances the performance of the semiconductor device 30.

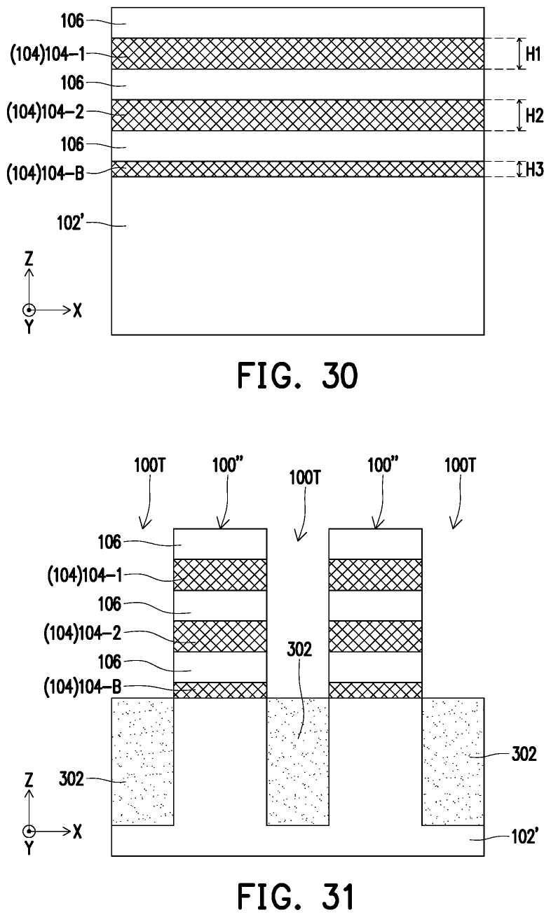

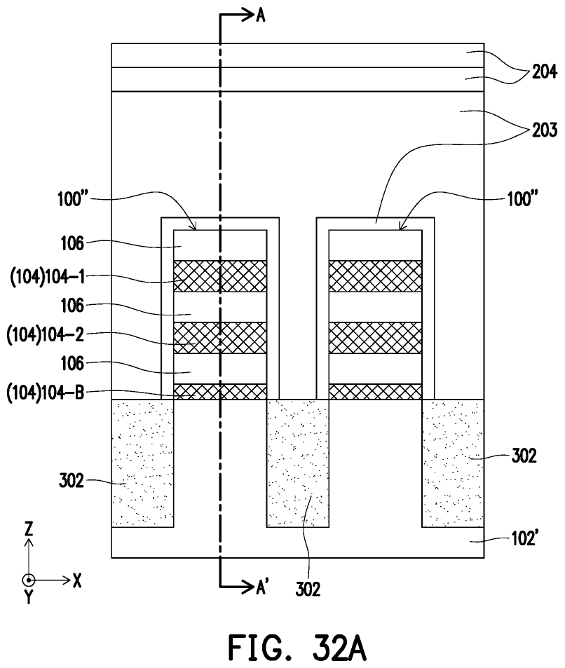

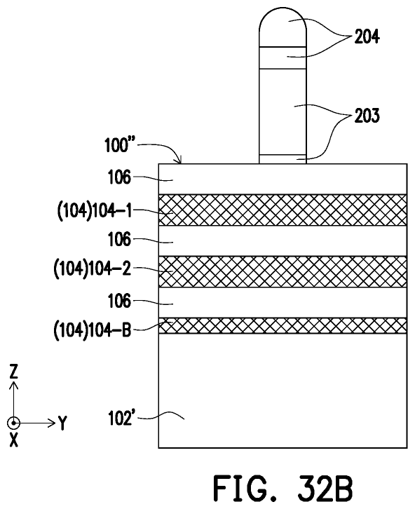

FIGS. 30-36 illustrate schematic cross-sectional views of intermediate steps during a process for forming a semiconductor device, in accordance with some embodiments. It should be noted that FIGS. 30-32A are cross-sectional views of the structure taken at the X-Z plane, FIG. 32B is a cross-sectional view of the structure illustrated in FIG. 32A taken along the line A-A′, and FIGS. 32B and 33-36 are cross-sectional views taken at the Y-Z plane and illustrating the following steps of forming a semiconductor device. Unless specified otherwise, like reference numerals in this embodiment represent like components in the embodiment shown in FIGS. 1-14 formed by like processes. Accordingly, the process steps and applicable materials may not be repeated herein. In addition, although FIGS. 30-36 are described as a series of acts, these acts are not limiting in that the order of the acts can be altered in other embodiments, and the methods disclosed are also applicable to other structures. Alternatively, some acts that are illustrated and/or described may be omitted in whole or in part.

Referring to FIG. 30 and with reference to FIG. 1, the structure shown in FIG. 30 is similar to the structure shown in FIG. 1, except for the bottommost first semiconductor layer 104-B. The bottommost first semiconductor layer 104-B may have a thickness H3 less than a thickness H1 of the topmost first semiconductor layer 104-1. The thickness H3 may be less than a thickness H2 of the middle first semiconductor layer 104-2, where the thicknesses H1 and H2 may be substantially equal or may be different. In some embodiments, the bottommost first semiconductor layer 104-B is the thinnest layer among the first semiconductor layers 104. The thickness of each of the first semiconductor layers 104 may range from few nanometers to few tens of nanometers. In some embodiments, a difference between the thickness H1 of the topmost first semiconductor layer 104-1 and the thickness H3 of the bottommost first semiconductor layer 104-B is in a range of about 0.5 nm to about 5.0 nm, although other differences are within the contemplated scope of the disclosure.

Referring to FIG. 31 and with reference to FIG. 30 and FIGS. 2-3, a portion of the stack of first semiconductor layers 104 and second semiconductor layers 106 along with the underlying portion of the semiconductor substrate 102′ may be removed to form trenches 100T, thereby defining the fin structure 100″. The removal process may be similar to the process described in FIG. 2. Next, the isolation structure 302 may be formed in lower portions of the trenches 100T as described in FIG. 3.

Referring to FIGS. 32A-32B and with reference to FIGS. 4A-4B, the dummy gate structure 203 and the mask layer 204 may be sequentially formed on the fin structures 100″. The materials and the forming processes of the dummy gate structure 203 and the mask layer 204 are similar to those of the dummy gate structure 203 and the mask layer 204 described in FIG. 4A-4B.

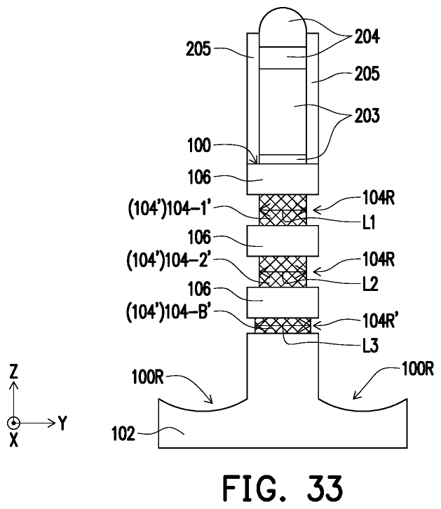

Referring to FIG. 33 and with reference to FIG. 32B and FIGS. 5-7, the gate spacer 205 may be conformally formed on the dummy gate structure 203, the mask layer 204, and the top of the fin structure 100″. Next, the respective fin structure 100″ and the semiconductor substrate 102′ may be partially removed to form the recesses 100R. Next, the first semiconductor layers 104 exposed by the recesses 100R may be removed in the lateral direction (e.g., the Y-direction) to form the respective etched fin structure 100 having etched first semiconductor layers 104′. The forming processes of the gate spacer 205, the recesses 100R, and the etched first semiconductor layers 104′ may be similar to the processes described in FIGS. 5-7. The thinner first semiconductor layer 104-B may slow down the lateral etching. For example, the bottommost first semiconductor layer 104-B′ having the smallest thickness is etched more slowly than the first semiconductor layers (e.g., 104-1′ and 104-2′) having greater thickness. For example, the dimension of the lateral recess 104R′ corresponding to the bottommost first semiconductor layer 104-B′ is less than that of the lateral recess 104R corresponding to the topmost first semiconductor layer 104-1′. The lateral dimension L3 of the bottommost first semiconductor layer 104-B′ may be greater than the lateral dimension L1 of the topmost first semiconductor layer 104-1′ and also greater than the lateral dimension L2 of the middle first semiconductor layer 104-2′.

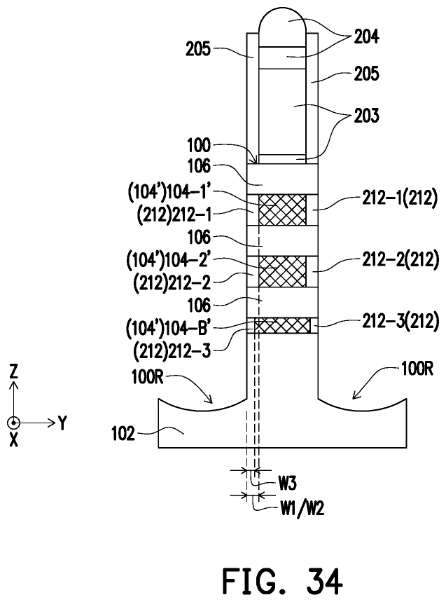

Referring to FIG. 34 and with reference to FIG. 33 and FIG. 8, the inner spacers 212 (e.g., 212-1, 212-2, and 212-3) may be formed in the lateral recesses 104R and 104R′. The material and the forming process of the inner spacers 212 may be similar to those of the inner spacers described in FIG. 8. Since the bottommost first semiconductor layer 104-B′ having the greater lateral dimension L3 than the lateral dimensions L1 and L2 of the overlying first semiconductor layers (104-1′ and 104-2′), the bottommost inner spacer 212-3 may have the thickness W3 less than the thickness W1 of the topmost inner spacer 212-1 and also less than the thickness W2 of the middle inner spacer 212-2.

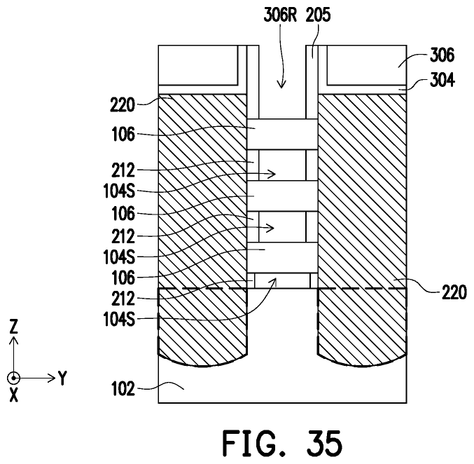

Referring to FIG. 35 and with reference to FIG. 34 and FIGS. 9-12, the epitaxial structures 220 may be epitaxially grown in the recesses 100R. As mentioned in FIG. 9, the respective epitaxial structure 220 may have different doping levels and may include an undoped region at the bottom, where the undoped region is illustrated in the dashed lines to indicate it may or may not exist. Next, the first ILD layer 306, the etch stop layer 304, and the recess 306R accessibly revealing the topmost one of the second semiconductor layers 106 of the respective etched fin structure 100 may be formed. The materials and the formation processes may be similar to the materials and the processes described in FIGS. 10-11. Next, the etched first semiconductor layers 104′ may be removed to form the recesses 104S (e.g., 104-1S, 104-2S, and 104-3S). The process may be similar to the process described in FIG. 12.

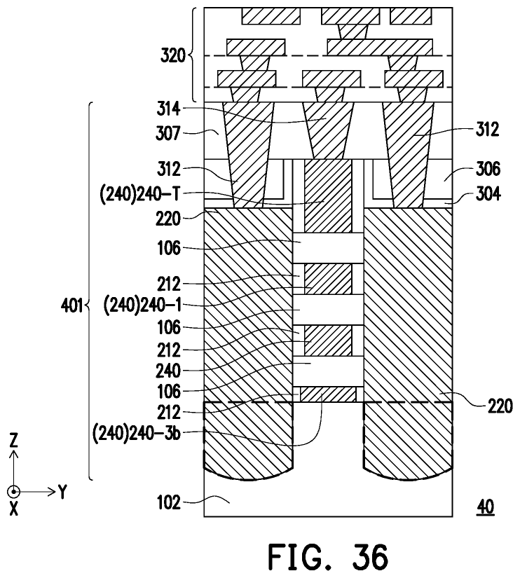

Referring to FIG. 36 and with reference to FIG. 35 and FIGS. 13-14, the gate structure 240 may be formed around the second semiconductor layers 106 and fill the recesses 306R and 104S. The material and the forming process of the gate structure 240 may be similar to those of the gate structure 240 described in FIG. 13. The bottommost gate section 240-3b may have a longer lateral dimension and a smaller vertical dimension than the topmost gate section 240-1. Next, the second ILD layer 307, the S/D contacts 312 extending through the second ILD layer 307 and the first ILD layer 306 to be coupled to the epitaxial structures 220, and the gate contact 314 extending through the second ILD layer 307 to be coupled to the topmost gate section 240T of the gate structure 240 may be formed. The front-side interconnect structure 320 may then be formed on the second ILD layer 307, the S/D contacts 312, and the gate contact 314. The materials and the forming processes of these features may be similar to those of the corresponding features described in FIG. 14.

With continued reference to FIG. 36 and FIG. 14, a semiconductor device 40 including a device layer 401 formed in/on the semiconductor substrate 102 and the front-side interconnect structure 320 formed on the device layer 401 is provided. The semiconductor device 40 is similar to the semiconductor device 10 illustrated in FIG. 14, except for the size of the bottom gate section and the forming method of the bottommost inner spacer and the bottommost gate section. In the illustrated embodiment, by configuring the thinner bottommost first semiconductor layer, the lateral recessing of the bottommost first semiconductor layer may be slowed down such that the bottommost inner spacer formed around the bottommost first semiconductor layer may have a smaller thickness compared to the thickness of the overlying inner spacers. By configuring the thinner bottommost inner spacer 212-3, the gate length of the bottommost gate section 240-3 may be increased and gate-junction overlapping may be improved. This in turn enhances the performance of the semiconductor device 40.

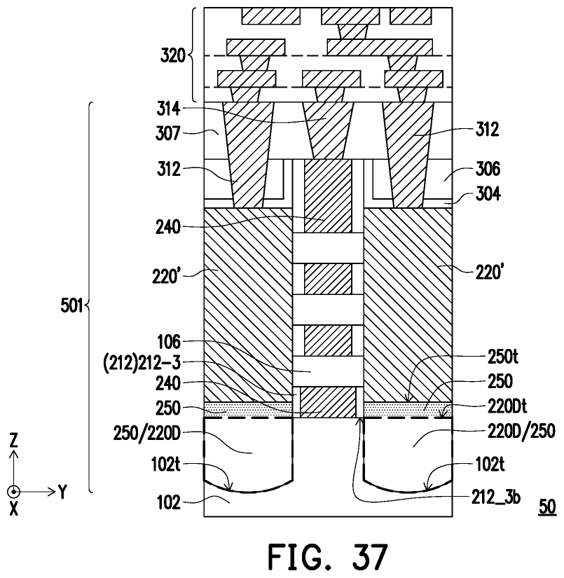

FIGS. 37 through 40 illustrate schematic cross-sectional views of variations of a semiconductor device, in accordance with some embodiments. Unless specified otherwise, like reference numerals in this embodiment represent like components in the embodiment shown in FIG. 14.

Referring to FIG. 37 and with reference to FIG. 14, the difference between a semiconductor device 50 shown in FIG. 37 and the semiconductor device 10 shown in FIG. 14 lies in that a device layer 501 of the semiconductor device 50 further includes bottom isolation structures 250 vertically interposed between the semiconductor substrate 102 and the S/D regions 220′ for prevention of leakage. The material of the bottom isolation structures 250 may include SiN, SiO₂, SION, SiCN, SiCON, SiCO, a high-k dielectric (e.g., HfO, AlO, etc.), compounds thereof, composites thereof, and/or combinations thereof. For example, the bottom isolation structures 250 are formed on the top surfaces 102t of the semiconductor substrate 102 after forming the inner spacers 212, and then the epitaxial structures (i.e. the S/D regions) 220′ are formed on the bottom isolation structures 250.

The bottom isolation structures 250 may isolate the overlying S/D regions 220′ from the underlying semiconductor substrate 102. The respective bottom isolation structure 250 may have a substantially flat top surface 250t, and the epitaxial structures 220′ formed on the top surfaces 250t of the bottom isolation structure 250 may have a substantially flat bottom surfaces. The respective bottom isolation structure 250 may partially cover the sidewall of the bottommost inner spacer 212-3. For example, the upper portion of the sidewall of the bottommost inner spacer 212-3 is exposed by the neighboring bottom isolation structures 250. Since the bottom isolation structures 250 exposes at least a portion of the bottommost inner spacer 212-3, the removal process of the etched first semiconductor layers 104′ as described in FIG. 12 will not be affected.

With continued reference to FIG. 37, lower portions of the bottom isolation structures 250 may be replaced with undoped epitaxial structures 220D (or the epitaxial structures that are substantially dopant-free), in some embodiments. The materials of the bottom isolation structures 250 and the undoped epitaxial structures 220D are different. The undoped epitaxial structures 220D may be epitaxially grown on the semiconductor substrate 102, and the respective undoped epitaxial structure 220D may not extend upward beyond the bottom surface 212_3b of the bottommost inner spacer 212_3. In some embodiments, the top surface 220Dt of the respective undoped epitaxial structure 220D is substantially level with the bottom surface 212_3b of the bottommost inner spacer 212_3 as pictured in FIG. 37, slightly elevated above the bottom surface 212_3b, or slightly below the bottom surface 212_3b. The bottom isolation structures 250 may be formed on the top surfaces 220Dt of the undoped epitaxial structures 220D and laterally adjoin the bottommost inner spacer 212-3.

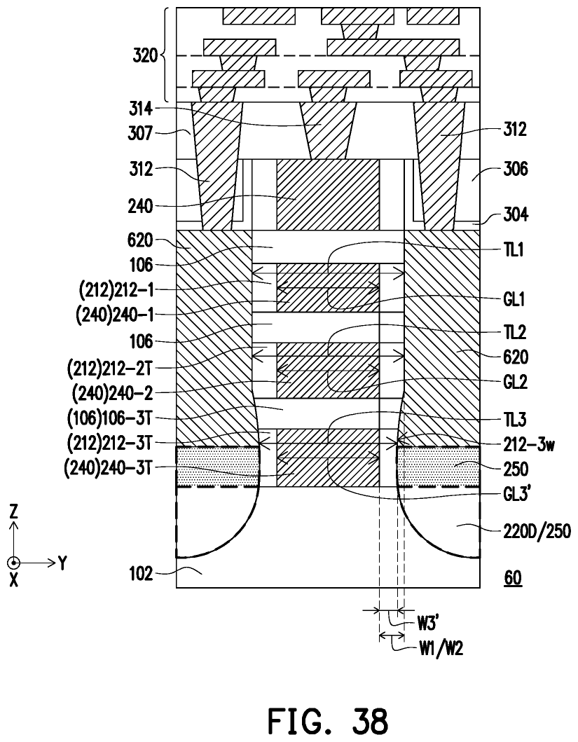

Referring to FIG. 38 and with reference to FIG. 14, the difference between a semiconductor device 60 shown in FIG. 38 and the semiconductor device 10 shown in FIG. 14 includes the cross-sectional profiles of the S/D regions 620, the bottommost inner spacer 212-3T, the bottommost channel layer 106-3T, and the middle inner spacer 212-2T. In some embodiments, the bottom section of the respective S/D region 620 laterally protrudes toward the bottommost inner spacer 212-3T and the bottommost channel layer 106-3T. The sidewalls of the bottommost inner spacer 212-3T and the bottommost channel layer 106-3T which are coupled to the S/D regions 620 may be curved/tilted (or concave toward the S/D regions 620). In some embodiments, the sidewall of the middle inner spacer 212-2T may have a curved lower portion connected to the sidewall of the bottommost channel layer 106-3T. The bottommost inner spacer 212-3T may have a variable thickness. For example, the minimum thickness W3′ of the bottommost inner spacer 212-3T is less than the maximum thickness W2 of the middle inner spacer 212-2T and also less than the maximum thickness W1 of the topmost inner spacer 212-1.

In some embodiments, a total lateral dimension TL3 of the lateral dimension GL3 of the bottommost gate section 240-3 and two times of the minimum thickness W3′ of the bottommost inner spacer 212-3T is less than a total lateral dimension TL2 of the lateral dimension GL2 of the middle gate section 240-2 and two times of the maximum thickness W2 of the middle inner spacer 212-2T. In some embodiments, the total lateral dimension TL3 is less than a total lateral dimension TL1 of the lateral dimension GL1 of the topmost gate section 240-1 and two times of the maximum thickness W1 of the topmost inner spacer 212-1. In some embodiments, the difference between the total lateral dimension TL3 and the total lateral dimension TL1 is less than 0, for example, in a range of about-5.0 nm and about 0 nm.

In some embodiments, before forming the epitaxial structures 620, the bottom isolation structures 250 are formed on the semiconductor substrate 102 as mentioned in FIG. 37. The bottom isolation structures 250 may be coupled to the curved sidewalls of the bottommost inner spacers 212-3T. In some embodiments, the undoped epitaxial structures 220D are formed on the semiconductor substrate 102-1, and the bottom isolation structures 250 are formed on the undoped epitaxial structures 220D as mentioned in FIG. 37. The undoped epitaxial structures 220D and the bottom isolation structures 250 are illustrated in the dashed lines to indicate they may or may not exist.

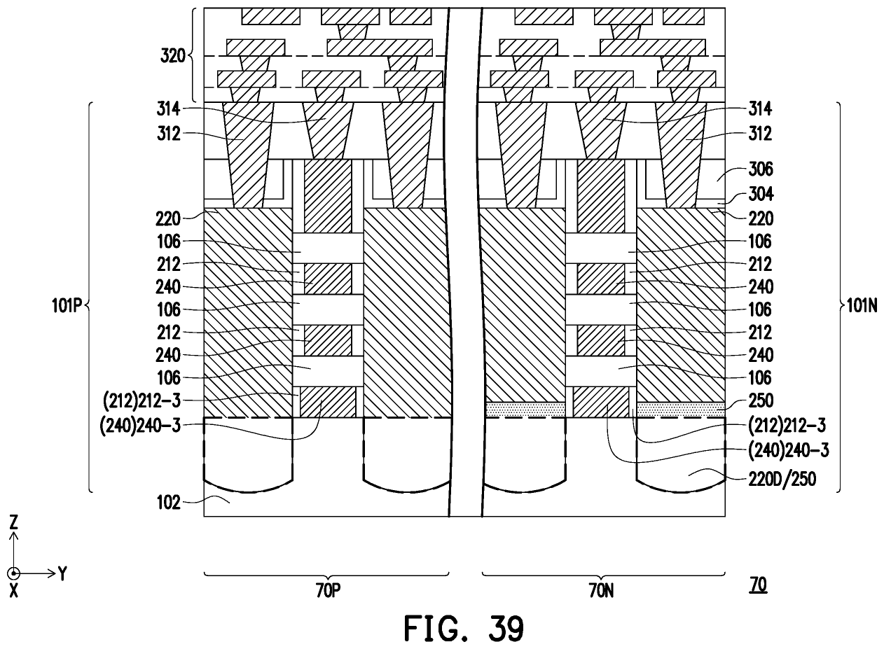

Referring to FIG. 39 and with reference to FIG. 14, a semiconductor device 70 is similar to the semiconductor device 10 shown in FIG. 14. For example, the semiconductor device 70 includes a p-type region (e.g., PMOS) 70P and an n-type region (e.g., NMOS) 70N. The device layer 101P in the p-type region 70P may be similar to the device layer 101N in the n-type region 70N. Dopants in the p-type region 70P and dopants in the n-type region 70N have different diffusion behavior, bottom leakage, and implantation amount, such that the configurations in the p-type region 70P and the n-type region 70N may be adjusted due to these factors. For example, the device layer 101N includes the bottom isolation structures 250 interposed between the S/D regions 220 and the semiconductor substrate 102, while the device layer 101P is free of the bottom isolation structures 250.

In alternative embodiments, the device layer 101P includes the bottom isolation structures 250 interposed between the S/D regions 220 and the semiconductor substrate 102, while the device layer 101N is free of the bottom isolation structures 250. In alternative embodiments, both of the device layers 101P and 101N include the bottom isolation structures 250 interposed between the S/D regions 220 and the semiconductor substrate 102. In other embodiments, both of the device layers 101P and 101N are free of the bottom isolation structures 250. In some embodiments, the lower portions of the bottom isolation structures 250 are replaced with undoped epitaxial structures 220D (or the epitaxial structures that are substantially dopant-free). The bottom isolation structures 250 and the undoped epitaxial structures 220D may be similar to the bottom isolation structures 250 and the undoped epitaxial structures 220D described in FIG. 37.

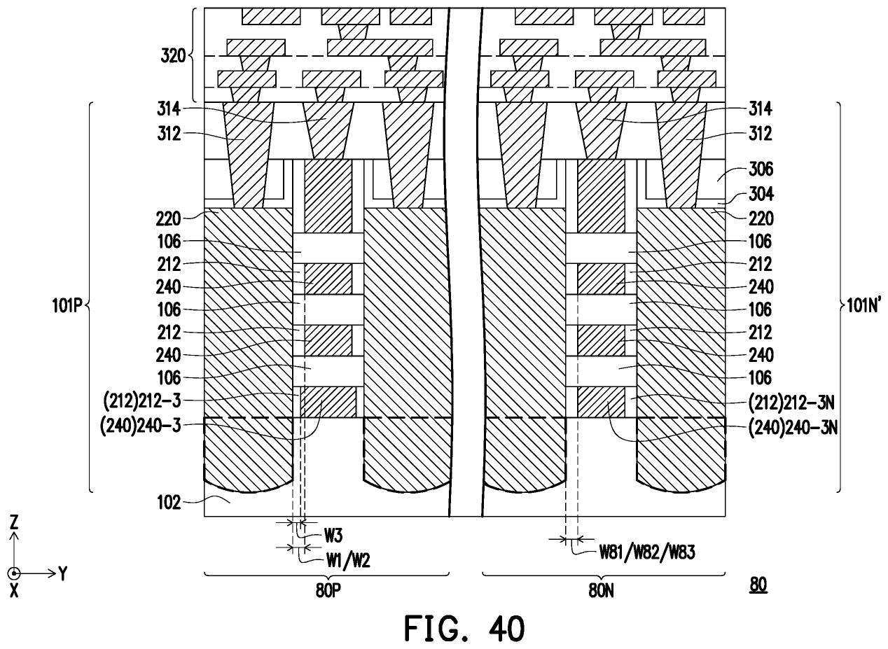

Referring to FIG. 40 and with reference to FIG. 39 and FIG. 14, a semiconductor device 80 is similar to the semiconductor device 10 shown in FIG. 14 and the semiconductor device 70 shown in FIG. 39. For example, the semiconductor device 80 includes the p-type region (e.g., PMOS) 80P and the n-type region (e.g., NMOS) 80N. Dopants in the p-type region 70P and in the n-type region 70N having different diffusion behavior may require varied requirements of thickness of inner spacers. For example, in the p-type region 80, the device layer 101P, similar to the device layer 101 described in FIG. 14, may have the bottommost inner spacer 212-3 thinner than the overlying inner spacers 212. The bottommost inner spacer 212-3N of the device layer 101N′ in the n-type region 80N may have a thickness W83 different from the thickness W3 of the bottommost inner spacer 212-3. For example, the thickness W83 is greater than the thickness W3. In some embodiments, the thickness W83 is substantially equal to the thickness W81 of the topmost inner spacer 212 and the thickness W82 of the middle inner spacer 212. The lateral dimension of the bottommost gate section 240-3N may be substantially equal to that of the overlaying gate sections 240. In some embodiments, the lateral dimension of the bottommost gate section 240-3N in the n-type region 80N is greater than that of the bottommost gate section 240-3 in the p-type region 80P.

In some embodiments, the thickness W2 of the middle inner spacer 212 in the p-type region 80P is less than the thickness W82 of the middle inner spacer 212 in the n-type region 80N. The thickness W1 of the topmost inner spacer 212 in the p-type region 80P may be less than the thickness W81 of the topmost inner spacer 212 in the n-type region 80N. In some embodiments, the thickness W83 is different from the thickness W82 and the thickness W81, and the first difference between the thicknesses W83 and the W81 in the n-type region 80N is different from the second difference between the thicknesses W3 and W1 in the p-type region 80P. For example, the difference between the first difference and the second difference is in a range of about 0.5 nm to about 4.0 nm.

In alternative embodiments, the bottommost inner spacer in the n-type region is thinner than the overlying inner spacers, while the bottommost inner spacer in the p-type region has a thickness substantially equal to the thicknesses of the overlying inner spacers. In alternative embodiments, the bottommost inner spacers in both of the p-type region and the n-type region are respectively thinner than the overlying inner spacers. In some embodiments, the device layer 101P/101N′ includes the bottom isolation structures (not shown) interposed between the S/D regions 220 and the semiconductor substrate 102. In some embodiments, the undoped epitaxial structures (not shown) are interposed between the bottom isolation structures and the semiconductor substrate 102. In some embodiments, in the p-type region 80P (and/or the n-type region 80N), the cross-sectional profiles of the S/D regions, the bottommost inner spacer, the bottommost channel layer, and the middle inner spacer may be replaced with the cross-sectional profiles described in FIG. 38. In some embodiments, the cross-sectional profiles of these features in the p-type region 80P are different from the cross-sectional profiles of these features in the n-type region 80N. The cross-sectional profiles may vary depending on process/product requirements.

According to some embodiments, a semiconductor device includes a semiconductor substrate, semiconductor nanosheets vertically stacked upon one another and disposed above the semiconductor substrate, a gate structure surrounding each of the semiconductor nanosheets, inner spacers laterally covering the gate structure and interposed between the semiconductor nanosheets, and S/D regions disposed over the semiconductor substrate and laterally abutting the semiconductor nanosheets. The semiconductor nanosheets serve as channel regions. A bottommost inner spacer of the inner spacers underlying a bottommost semiconductor nanosheet of the semiconductor nanosheets is thinner than a topmost inner spacer of the inner spacers underlying a topmost semiconductor nanosheet of the semiconductor nanosheets. The S/D regions are separated from the gate structure through the inner spacers.

According to some alternative embodiments, a semiconductor device includes a semiconductor substrate and a device layer disposed on the semiconductor substrate. The device layer includes channel regions vertically stacked upon one another, a gate structure surrounding each of the channel regions, S/D regions disposed on the semiconductor substrate and laterally coupled to the channel regions, and inner spacers laterally separating the S/D regions from the gate structure. The gate structure includes a topmost gate section and a bottommost gate section between the topmost gate section and the semiconductor substrate, and a lateral dimension of the bottommost gate section is greater than that of the topmost gate section.

According to some alternative embodiments, a manufacturing method for a semiconductor device includes forming a fin structure over a semiconductor substrate, where the fin structure includes semiconductor channel layers and semiconductor sacrificial layers alternatively formed on top of one another; laterally recessing the semiconductor sacrificial layers, where after the laterally recessing, a lateral dimension of a bottommost semiconductor sacrificial layer of the semiconductor sacrificial layers is greater than that of a topmost semiconductor sacrificial layer of the semiconductor sacrificial layers; forming inner spacers on sidewalls of the semiconductor sacrificial layers after the laterally recessing, where a bottommost inner spacer of the inner spacers surrounding the bottommost semiconductor sacrificial layer is thinner than a topmost semiconductor inner spacer of the semiconductor sacrificial layers inner spacers surrounding the topmost semiconductor sacrificial layer; forming S/D regions on the semiconductor substrate to be laterally coupled to the inner spacers and the semiconductor channel layers; and replacing the semiconductor sacrificial layers with a gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a semiconductor substrate;
semiconductor nanosheets vertically stacked upon one another, disposed above the semiconductor substrate, and serving as channel regions;
a gate structure surrounding each of the semiconductor nanosheets;
inner spacers laterally covering the gate structure and interposed between the semiconductor nanosheets, wherein a bottommost inner spacer of the inner spacers underlying a bottommost semiconductor nanosheet of the semiconductor nanosheets is thinner than a topmost inner spacer of the inner spacers underlying a topmost semiconductor nanosheet of the semiconductor nanosheets; and
source/drain (S/D) regions disposed over the semiconductor substrate and laterally abutting the semiconductor nanosheets, the S/D regions being separated from the gate structure through the inner spacers.

2. The semiconductor device of claim 1, wherein a bottommost gate section of the gate structure laterally surrounded by the bottommost inner spacer comprises a lateral dimension greater than a lateral dimension of a topmost gate section of the gate structure laterally surrounded by the topmost inner spacer.

3. The semiconductor device of claim 1, wherein the semiconductor substrate comprises:
a doped layer physically connected to the S/D regions and the bottommost inner spacer.

4. The semiconductor device of claim 1, further comprising:
a bottom isolation structure vertically interposed between the semiconductor substrate and the S/D regions.

5. The semiconductor device of claim 4, wherein the bottom isolation structure physically connected to at least a lower region of the bottommost inner spacer.

6. The semiconductor device of claim 4, wherein the semiconductor substrate comprises a p-type region and an n-type region, and the bottom isolation structure is disposed in at least one selected from a group of the p-type region and the n-type region.

7. The semiconductor device of claim 4, further comprising:
an epitaxial structure vertically interposed between the semiconductor substrate and the bottom isolation structure, the epitaxial structure being substantially dopant-free.

8. The semiconductor device of claim 1, wherein the bottommost inner spacer comprises a curved sidewall concave toward the S/D regions.

9. The semiconductor device of claim 8, the bottommost semiconductor nanosheet comprises a tilted sidewall connected to the curved sidewall of the bottommost inner spacer and laterally adjoining the S/D regions.

10. The semiconductor device of claim 1, wherein the semiconductor substrate comprises a p-type region and an n-type region, and a thickness of the bottommost inner spacer in the p-type region is different from that of the bottommost inner spacer in the n-type region.

11. A semiconductor device, comprising:
a semiconductor substrate; and
a device layer disposed on the semiconductor substrate, the device layer comprising:
channel regions vertically stacked upon one another;
a gate structure surrounding each of the channel regions, the gate structure comprising a topmost gate section and a bottommost gate section between the topmost gate section and the semiconductor substrate, and a lateral dimension of the bottommost gate section being greater than that of the topmost gate section;
S/D regions disposed on the semiconductor substrate and laterally coupled to the channel regions; and
inner spacers laterally separating the S/D regions from the gate structure.

12. The semiconductor device of claim 11, wherein the inner spacers comprises:
a topmost inner spacer laterally surrounding the topmost gate section; and
a bottommost inner spacer laterally surrounding the bottommost gate section, wherein the bottommost inner spacer is thinner than the topmost inner spacer.

13. The semiconductor device of claim 11, wherein the semiconductor substrate comprises:
a doped layer physically connected to the S/D regions and the bottommost gate section.

14. The semiconductor device of claim 11, further comprising:
a bottom isolation structure vertically separating the S/D regions from the semiconductor substrate.

15. A manufacturing method for a semiconductor device, comprising:
forming a fin structure over a semiconductor substrate, wherein the fin structure comprises semiconductor channel layers and semiconductor sacrificial layers alternatively formed on top of one another;
laterally recessing the semiconductor sacrificial layers, wherein after the laterally recessing, a lateral dimension of a bottommost semiconductor sacrificial layer of the semiconductor sacrificial layers is greater than that of a topmost semiconductor sacrificial layer of the semiconductor sacrificial layers;
forming inner spacers on sidewalls of the semiconductor sacrificial layers after the laterally recessing, wherein a bottommost inner spacer of the inner spacers surrounding the bottommost semiconductor sacrificial layer is thinner than a topmost semiconductor inner spacer of the semiconductor sacrificial layers inner spacers surrounding the topmost semiconductor sacrificial layer;
forming S/D regions on the semiconductor substrate to be laterally coupled to the inner spacers and the semiconductor channel layers; and
replacing the semiconductor sacrificial layers with a gate structure.

16. The manufacturing method of claim 15, wherein forming the fin structure over the semiconductor substrate comprises:
forming the topmost semiconductor sacrificial layer over the bottommost semiconductor sacrificial layer, wherein the topmost semiconductor sacrificial layer contains silicon germanium with a first percentage of germanium, and the bottommost semiconductor sacrificial layer contains silicon germanium with a second percentage of germanium which is less than the first percentage.

17. The manufacturing method of claim 15, further comprising:
forming a doped layer in the semiconductor substrate before forming the fin structure over the semiconductor substrate; and
diffusing dopants from the doped layer into the bottommost semiconductor sacrificial layer after forming the fin structure over the semiconductor substrate and before laterally recessing the semiconductor sacrificial layers.

18. The manufacturing method of claim 15, further comprising:
forming a doped region in the bottommost semiconductor sacrificial layer before forming the fin structure over the semiconductor substrate; and
laterally recessing the semiconductor sacrificial layers by etching, wherein the bottommost semiconductor sacrificial layer with the doped region is etched more slowly than the topmost semiconductor sacrificial layer.

19. The manufacturing method of claim 15, further comprising:
forming the topmost semiconductor sacrificial layer over the bottommost semiconductor sacrificial layer before forming the fin structure over the semiconductor substrate, wherein the bottommost semiconductor sacrificial layer is thinner than the topmost semiconductor sacrificial layer.

20. The manufacturing method of claim 15, further comprising:
forming bottom isolation structures on the semiconductor substrate after forming the inner spacers; and
forming the S/D regions on the bottom isolation structures, wherein the bottom isolation structures vertically separate the S/D regions from the semiconductor substrate.
